(19) United States
(12) Patent Application Publication
(10) Pub. No.: US 2014/0158303 A1
(43) Pub. Date: Jun. 12, 2014

(54) BONDING SYSTEM, SUBSTRATE PROCESSING SYSTEM, AND BONDING METHOD

(71) Applicants: Osamu Hirakawa, Kumamoto (JP); Naoto Yoshitaka, Kumamoto (JP); Masataka Matsunaga, Kumamoto (JP); Norihiko Okamoto, Kumamoto (JP)

(72) Inventors: Osamu Hirakawa, Kumamoto (JP); Naoto Yoshitaka, Kumamoto (JP); Masataka Matsunaga, Kumamoto (JP); Norihiko Okamoto, Kumamoto (JP)

(73) Assignee: TOKYO ELECTRON LIMITED, Tokyo (JP)

(21) Appl. No.: 14/131,247

(22) PCT Filed: Jun. 25, 2012
(86) PCT No.: PCT/JP2012/066135

§ 371 Date: Jan. 7, 2014

(30) Foreign Application Priority Data
Jul. 15, 2011 (JP) 2011-156437

(51) Int. Cl. H01L 21/677

(52) U.S. Cl. CPC H01L 21/677
USPC 156/379; 156/499; 156/389

(57) ABSTRACT

This bonding system comprises a bonding processing station and a carry in/out station which carries a substrate to be processed, a supporting substrate or a bonded substrate that is obtained by bonding a substrate to be processed and a supporting substrate into/out of the bonding processing station. The bonding processing station comprises a coating device which applies an adhesive to the substrate to be processed or the supporting substrate and a heat treatment device that heats the substrate, to which the adhesive has been applied. In addition, a bonding device turns over one of the substrates, and presses the overturned substrate against the other substrate with an adhesive therebetween, thereby bonding the substrates together. A conveyance region conveys the substrate(s) to the coating device, the heat treatment device and the bonding device.

### TECHNICAL FIELD

The present disclosure relates to a bonding system that bonds a substrate to be processed and a supporting substrate with each other, a substrate processing system provided with the bonding system, and a bonding method using the bonding system.

### BACKGROUND

For example, in a semiconductor device manufacturing process, the enlargement of semiconductor wafers (hereinafter, referred to as a “wafer”) is continuing in recent years. In addition, in a specific process such as, for example, mounting, thinning of wafers is requested. For example, when a thin wafer with a large diameter is conveyed or polished as it is, warpage or crack may occur in the wafer. For this reason, such a wafer is bonded to a supporting substrate such as, for example, a wafer or a glass substrate, so as to reinforce the wafer.

When bonding such a wafer and a supporting substrate with each other, for example, a bonding device is used to interpose an adhesive between the wafer and the supporting substrate. The bonding device includes a first holding member configured to hold, for example, a wafer, a second holding member configured to hold a supporting substrate, a heating mechanism configured to heat an adhesive interposed between the wafer and the supporting substrate, and a moving mechanism configured to move the first holding member or the second holding member up and down. In addition, in the bonding device, the adhesive is supplied between the wafer and the supporting substrate, the adhesive is heated, and then, the wafer and the supporting substrate are pressed to be bonded with each other (Patent Document 1).

### PRIOR ART DOCUMENT

### Patent Document

Patent Document 1: Japanese Patent Laid-Open Publication 2008-182016

### DISCLOSURE OF THE INVENTION

### Problems to be Solved

However, when the bonding device disclosed in Patent Document 1 is used, the supplying of the adhesive, the heating of the adhesive, and the pressing of the wafer and the supporting substrate are all performed within the single bonding device. Thus, a large amount of time is required for bonding the wafer and the supporting substrate with each other. Therefore, there is a room for improvement in entire bonding processing throughput.

The present invention has been made in an effort to solve the problems as described above, and an object of the present invention is to improve bonding processing throughput by efficiently performing the bonding of a substrate to be processed and a supporting substrate.

### Means to Solve the Problems

In order to achieve the objects as described above, the present disclosure provides a bonding system that bonds a substrate to be processed and a supporting substrate with each other. The bonding system includes: a bonding processing station configured to perform a predetermined processing on a substrate to be processed and a supporting substrate; and a carry in/out station configured to carry a substrate to be processed, a supporting substrate, or a superimposed substrate obtained by bonding a substrate to be processed and a supporting substrate with each other into/out of the bonding processing station.

The bonding processing station includes: a coating device configured to coat an adhesive to the substrate to be processed or the supporting substrate; a heat treatment device configured to heat the substrate to be processed or the supporting substrate which is coated with the adhesive to a predetermined temperature; a bonding device configured to invert front and back surfaces of the supporting substrate that is bonded to the substrate to be processed that is coated with the adhesive and heated to the predetermined temperature or the substrate to be processed that is bonded to the supporting substrate that is coated with the adhesive and heated to the predetermined temperature, and press the substrate to be processed and the supporting substrate with the adhesive being interposed therebetween, thereby bonding the substrate to be processed and the supporting substrate with each other; and a conveyance region configured to convey the substrate to be processed, the supporting substrate or the superimposed substrate to the coating device, the heat treatment device, and the bonding device.

According to the bonding system of the present disclosure, in the coating device and the heat treatment device, for example, a substrate to be processed is subjected to sequential processings in such a manner that the substrate to be processed is coated with an adhesive and heated to a predetermined temperature, and in the bonding device, the front and back surfaces of, for example, a supporting substrate, are inverted. Then, in the bonding device, the substrate to be processed that is coated with the adhesive and heated to the predetermined temperature and the supporting substrate of which the front and back surfaces are inverted are bonded with each other. Thus, according to the present disclosure, the substrate to be processed and the supporting substrate may be processed at the same time. In addition, while the substrate to be processed and the supporting substrate are bonded with each other in the bonding device, other substrates to be processed and supporting substrates may be processed in the coating device, the heat treatment device and the bonding device. Accordingly, the substrates to be processed and the supporting substrates may be efficiently bonded with each other and thus, the bonding processing throughput may be improved. Meanwhile, in the above description, the substrate to be processed is coated with the adhesive and the front and back surfaces of the supporting substrate are inverted. However, the supporting substrate may be coated with the adhesive and the front and back surface of the substrate to be processed may be inverted.

A substrate processing system according to another aspect of the present disclosure is provided with the above-described bonding system and further includes a separating system configured to separate the superimposed substrate bonded in the bonding system into the substrate to be processed and the supporting substrate. The separating system includes: a separating processing station configured to perform a predetermined processing on the substrate to be processed, the supporting substrate, and the superimposed substrate; a carry in/out station configured to carry the substrate to be processed, the supporting substrate, or the superimposed substrate into/out of the separating processing station; and a conveyance device configured to convey the substrate to be processed, the supporting substrate or the superimposed substrate between the separating processing station and the carry in/out station.

According to another aspect, the present disclosure provides a method of boding a substrate to be processed and a supporting substrate with each other using a bonding system. The bonding system includes: a bonding processing station; and a carry in/out station. The bonding processing station includes: a coating device configured to coat an adhesive to a substrate to be processed or a supporting substrate; a heat treatment device configured to heat the substrate to be processed or the supporting substrate which is coated with the adhesive to a predetermined temperature; a bonding device configured to invert front and back surfaces of the supporting substrate that is bonded to the substrate to be processed that is coated with the adhesive and heated to the predetermined temperature or the substrate to be processed which is bonded to the supporting substrate which is coated with the adhesive and heated to the predetermined temperature and press the substrate to be processed and the supporting substrate with the adhesive being interposed therebetween, thereby bonding the substrate to be processed and the supporting substrate with each other; and a conveyance region configured to convey the substrate to be processed, the supporting substrate or the superimposed substrate to the coating device, the heat treatment device, and the bonding device. The carry in/out station is configured to carry a substrate to be processed, a supporting substrate, or a superimposed substrate obtained by bonding a substrate to be processed and a supporting substrate with each other into/out of the bonding processing station. In addition, the bonding method includes: an adhesive coating process of coating an adhesive to a substrate to be processed or a supporting substrate in the coating device and then, heating the substrate to be processed or the supporting substrate to a predetermined temperature in the heat treatment device; an inverting process of inverting, in the bonding device, front and back surfaces of the supporting substrate that is bonded to the substrate to be processed which is coated with the adhesive and heated to the predetermined temperature in the adhesive coating process or the substrate to be processed that is bonded to the supporting substrate that is coated with the adhesive and heated to the predetermined temperature in the adhesive coating process; and a bonding process of bonding, in the bonding device, the substrate to be processed or the supporting substrate which is coated with the adhesive and heated to the predetermined temperature in the adhesive coating process and the supporting substrate or the substrate to be processed of which the front and back surfaces are inverted in the inverting process, with each other.

### Effect of the Invention

According to the present disclosure, bonding of a substrate to be processed and a supporting substrate may be efficiently performed and thus, the bonding processing throughput may be improved.

### BRIEF DESCRIPTION OF THE DRAWINGS

FIG. 1 is a plan view schematically illustrating a configuration of a bonding system according to an exemplary embodiment.

FIG. 2 is a side view schematically illustrating an internal configuration of the bonding system.

FIG. 3 is a side view illustrating a wafer to be processed and a supporting wafer.

FIG. 4 is a horizontal cross-sectional view schematically illustrating a configuration of a bonding device.

FIG. 5 is a plan view schematically illustrating a configuration of a delivery section.

FIG. 6 is a plan view schematically illustrating a configuration of a delivery arm.

FIG. 7 is a side view schematically illustrating the configuration of the delivery arm.

FIG. 8 is a plan view schematically illustrating a configuration of an inverting section.

FIG. 9 is a side view schematically illustrating the configuration of the inverting section.

FIG. 10 is another side view schematically illustrating the configuration of the inverting section.

FIG. 11 is a side view schematically illustrating holding arms and a holding member.

FIG. 12 is an explanatory view illustrating a positional relationship between the delivery section and the inverting section.

FIG. 13 is a side view schematically illustrating a configuration of a conveyance section.

FIG. 14 is an explanatory view illustrating a state where the conveyance section is arranged in the bonding device.

FIG. 15 is a plan view schematically illustrating a configuration of a first conveyance arm.

FIG. 16 is a side view schematically illustrating a configuration of the first conveyance arm.

FIG. 17 is a plan view schematically illustrating a configuration of a second conveyance arm.

FIG. 18 is a side view schematically illustrating a configuration of the second conveyance arm.

FIG. 19 is an explanatory view illustrating a second holding unit formed with cutouts.

FIG. 20 is a vertical cross-sectional view schematically illustrating a configuration of a bonding section.

FIG. 21 is a vertical cross-sectional view schematically illustrating the configuration of the bonding section.

FIG. 22 is a vertical cross-sectional view schematically illustrating a configuration of a coating device.

FIG. 23 is a horizontal cross-sectional view schematically illustrating the configuration of the coating device.

FIG. 24 is a vertical cross-sectional view illustrating a configuration of a heat treatment device.

FIG. 25 is a horizontal cross-sectional view schematically illustrating the configuration of the heat treatment device.

FIG. 26 is an explanatory view illustrating air flow generated in the bonding system.

FIG. 27 is a flow chart illustrating main processes in a bonding processing.

FIG. 28 is an explanatory view illustrating a state where a first holding unit is moved up.

FIG. 29 is an explanatory view illustrating a state where the central portion of a second holding unit is flexed.

FIG. 30 is an explanatory view illustrating a state where the entire bonded surface of a supporting wafer is in contact with the entire bonded surface of a wafer to be processed.

FIG. 31 is an explanatory view illustrating a state where the wafer to be processed and the supporting wafer are bonded with each other.

FIG. 32 is a side view schematically illustrating an internal configuration of a bonding system according to another exemplary embodiment.

FIG. 33 is a vertical cross-sectional view schematically illustrating a configuration of an inspection device.

FIG. 34 is a horizontal cross-sectional view schematically illustrating the configuration of the inspection device.

FIG. 35 is a plan view schematically illustrating a configuration of a substrate processing system including a bonding system and a separating system.

FIG. 36 is a side view illustrating a wafer to be processed and a supporting wafer.

FIG. 37 is a vertical cross-sectional view schematically illustrating a configuration of a separating device.

FIG. 38 is a vertical cross-sectional view schematically illustrating a configuration of a first cleaning device.

FIG. 39 is a horizontal cross-sectional view schematically illustrating the configuration of the first cleaning device.

FIG. 40 is a vertical cross-sectional view schematically illustrating a configuration of a second cleaning device.

FIG. 41 is a side view schematically illustrating a configuration of a second conveyance device.

FIG. 42 is a flow chart illustrating main processes of a separating processing.

FIG. 43 is an explanatory view illustrating a state where a superimposed wafer is held by the first holding unit and the second holding unit.

FIG. 44 is an explanatory view illustrating a state where the second holding unit is moved in the vertical direction and in the horizontal direction.

FIG. 45 is an explanatory view illustrating a state where the wafer to be processed and the supporting wafer are separated from each other.

FIG. 46 is an explanatory view illustrating a state where a wafer to be processed is delivered from the first holding unit to a Bernoulli chuck.

FIG. 47 is an explanatory view illustrating a state where the wafer to be processed is delivered from the Bernoulli chuck to a porous chuck.

FIG. 48 is a plan view schematically illustrating a configuration of a separating system according to still another exemplary embodiment.

FIG. 49 is a plan view schematically illustrating a configuration of a separating system according to yet another exemplary embodiment.

### DETAILED DESCRIPTION TO EXECUTE THE INVENTION

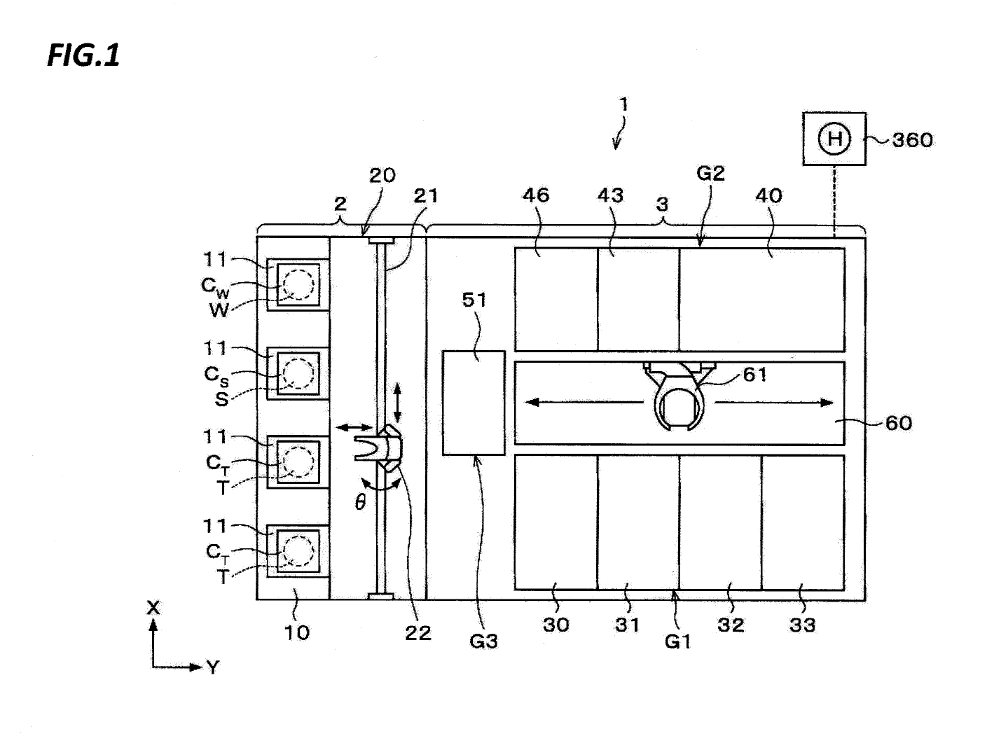

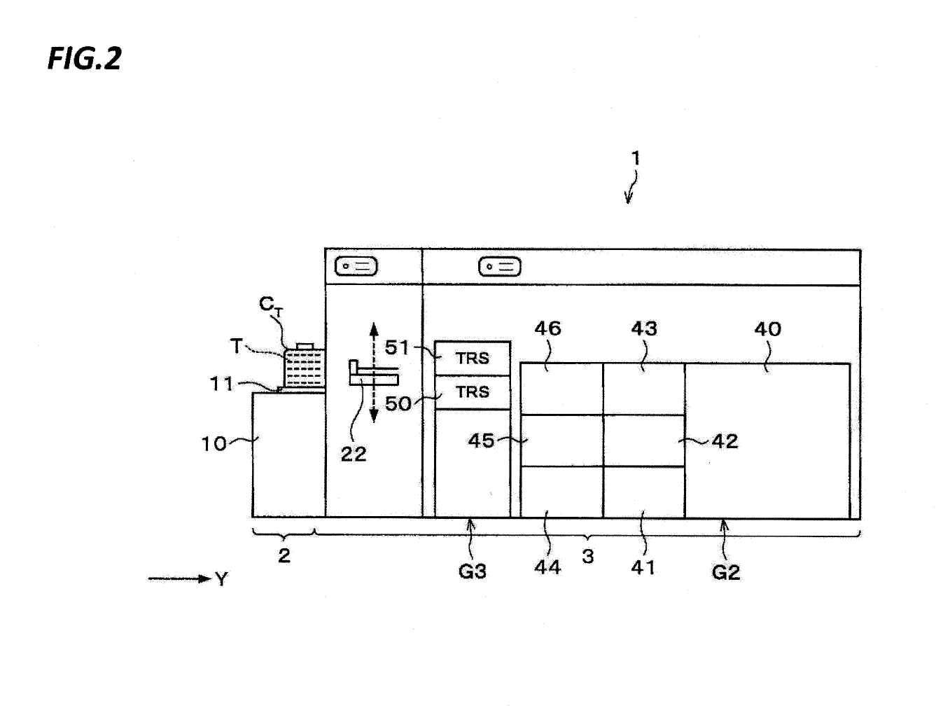

Hereinafter, exemplary embodiments of the present disclosure will be described. FIG. 1 is a plan view schematically illustrating a configuration of a bonding system 1 according to an exemplary embodiment. FIG. 2 is a side view schematically illustrating an internal configuration of the bonding system 1.

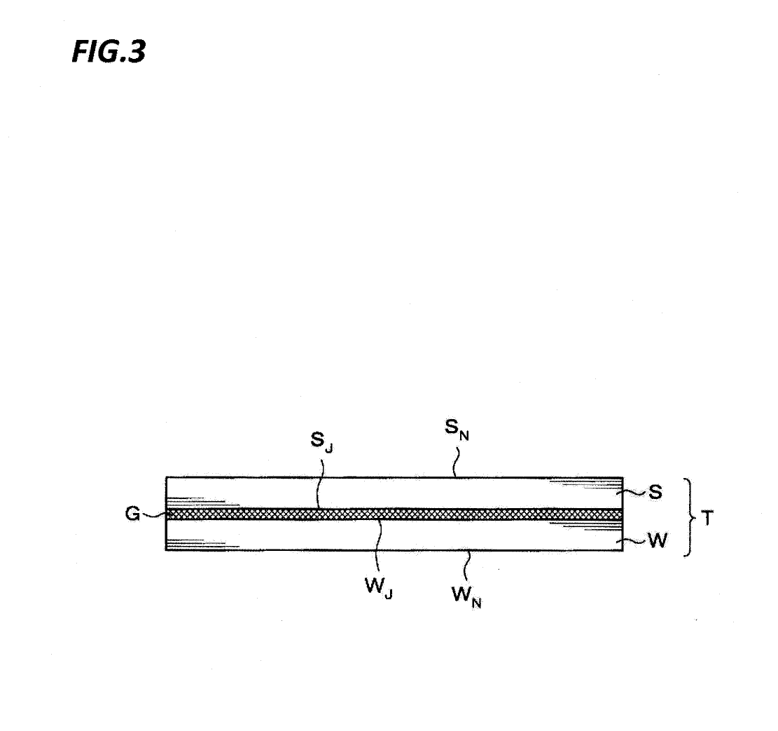

In the bonding system 1, as illustrated in FIG. 3, a wafer to be processed W as a substrate to be processed and a supporting wafer S as a supporting substrate are bonded with each other through, for example, an adhesive G. Hereinafter, in the wafer to be processed W, a surface to be bonded to the supporting wafer S through the adhesive G will be referred to as a “bonded surface W_{J}” as a front surface and the surface opposite to the bonded surface W_{J} will be referred to as a “non-bonded surface W_{N}” as a back surface. Similarly, in the supporting wafer S, a surface of the supporting wafer S bonded to the wafer to be processed W though the adhesive G will be referred to as a “bonded surface S_{J}” as a front surface and the surface opposite to the bonded surface S_{J} will be referred to as a “non-bonded surface S_{N}” as a back surface. Further, in the bonding system 1, the wafer to be processed W and the supporting wafer S are bonded with each other so as to form a superimposed wafer T as a superimposed substrate. Meanwhile, the wafer to be processed W is a wafer which will be made into a product in which, for example, the bonded surface W_{J} is formed with a plurality of electronic circuits and the non-bonded surface W_{N} is subjected to a polishing processing. In addition, the supporting wafer S has a diameter which is the same as the diameter of the wafer to be processed W and serves to support the wafer to be processed W. In the present exemplary embodiment, descriptions will be made on a case in which a wafer is used as the supporting substrate. However, any other substrate such as, for example, a glass substrate, may be used as for the supporting substrate.

As illustrated in FIG. 1, the bonding system 1 includes: a carry in/out station 2 configured to carry cassettes C_{W}, C_{S}, C_{T} which are capable of accommodating a plurality of wafers to be processed W, a plurality of supporting wafers S, and a plurality of superimposed wafers T respectively, to or from, for example, the outside; and a bonding processing station 3 which is provided with various processing devices each of which performs a predetermined processing in relation to the wafers to be processed W, the supporting wafers S, and the superimposed wafers T. The carry in/out station 2 and the bonding processing station 3 are integrally connected with each other.

The carry in/out station 2 is provided with a cassette mounting stage 10. The cassette mounting stage 10 is provided with a plurality of (e.g., four) cassette mounting plates 11. The cassette mounting plates 11 are arranged in a row in the X direction (in the vertical direction in FIG. 1). The cassettes C_{W}, C_{S}, C_{T} may be mounted on the cassette mounting plates 11 when the cassettes C_{W}, C_{S}, C_{T} are carried to or from the outside of the bonding system 1. As described above, the carry in/out station 2 is configured to be capable of holding a plurality of wafers to be processed W, a plurality of supporting wafers S, and a plurality of superimposed wafers T. Meanwhile, the number of the cassette mounting plates 11 is not limited to the present exemplary embodiment and may be optionally determined. Further, one of the cassettes may be used for recovering defective wafers. That is, when a problem occurs in bonding wafers to be processed W and supporting wafers S due to various reasons, the cassette allows problematic wafers to be separated from other normal superimposed wafers T. In the present exemplary embodiment, one cassette C_{T} among the plurality of cassettes C_{T} is used for recovering defective wafers and the other cassettes C_{T} are used for accommodating normal superimposed wafers T.

In the carry in/out station 2, a wafer conveyance section 20 is installed adjacent to the cassette mounting stage 10. In the wafer conveyance section 20, a wafer conveyance device 22 is installed to be capable of being moved on a conveyance path 21 that extends in the X direction. The wafer conveyance device 22 is also capable of being moved in the vertical direction and around the vertical axis (O-direction) so as to convey the wafers to be processed W, the supporting wafers S, and the superimposed wafers T between the cassettes C_{W}, C_{S}, C_{T} on the respective cassette mounting plates 11 and transition devices 50, 51 of a third processing block G3 of the bonding processing station 3 which will be described later.

The bonding processing station 3 is formed with a plurality of (e.g., three) processing blocks G1, G2, G3 which are provided with various processing devices. For example, a first processing block G1 is formed, for example, at the front side of the bonding processing station 3 (at the negative side in the X direction in FIG. 1), and a second processing block G2 is formed at the back side of the bonding processing station 3 (at the positive side in the −X direction in FIG. 1. Further, the third processing block G3 is formed at the carry in/out station 2 side of the bonding processing station 3 (at the negative side in the Y direction in FIG. 1).

For example, in the first processing block G1, bonding devices 30 to 33 configured to press the wafers to be processed W and the supporting wafers S to be bonded with each other through the adhesive G are arranged in a row in this order in the Y direction from the carry in/out station 2 side.

For example, in the second processing block G2, a coating device 40 configured to coat an adhesive G on a wafer to be processed W, heat treatment devices 41, 42, 43 configured to heat the wafer to be processed W coated with the adhesive G to a predetermined temperature, and heat treatment devices 44, 45, 46, which are the same as those of the heat treatment devices 44, 45, 46, are arranged in this order and parallel to each other in the direction toward the carry in/out station 2 (at the negative side in the Y direction in FIG. 1), as illustrated in FIG. 2. The heat treatment devices 41, 42, 43 and the heat treatment devices 44, 45, and 46 are arranged in three tiers in the indicated order from the bottom in each set. However, the number or the vertical or horizontal arrangement of the heat treatment devices 41 to 46 may be optionally set.

For example, in the third processing block G3, transition devices 50, 51 for the wafers to be processed W, the supporting wafers S, and the superimposed wafers T are arranged in two tires in this order from the bottom.

As illustrated in FIG. 1, a wafer conveyance region 60 is formed in a region surrounded by the first to third processing blocks G1 to G3. In the wafer conveyance region 60, for example, a wafer conveyance device 61 is disposed. Meanwhile, the pressure within the wafer conveyance region 60 is equal to or higher than atmospheric pressure and so-called atmospheric system conveyance of a wafer to be processed W, a supporting wafer S, and a superimposed wafer T is performed in the wafer conveyance region 60.

The wafer conveyance device 61 is provided with a conveyance arm which is moveable, for example, in the vertical direction (in the Y direction), in the horizontal direction (in the X direction), and around a vertical axis. The wafer conveyance device 61 is moved within the wafer conveyance region 60 so as to convey the wafer to be processed W, the supporting wafer S, the superimposed wafer T to predetermined devices within the first processing block G1, the second processing block G2, and the third processing block G3 around the wafer conveyance device 61.

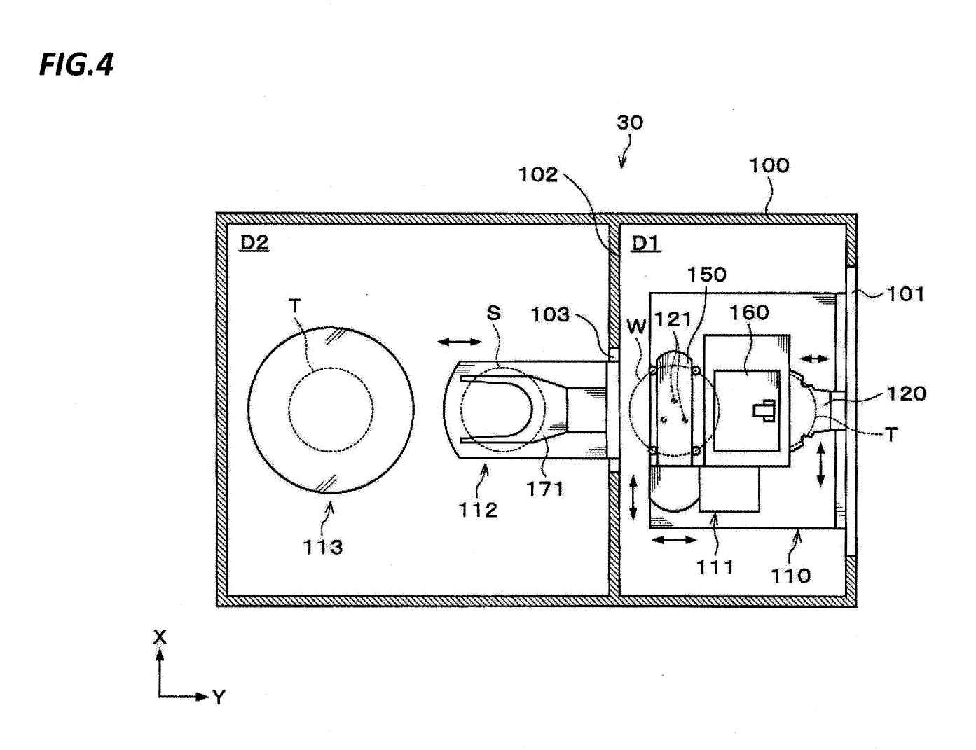

Next, descriptions will be made on the configurations of the above-described bonding devices 30 to 33. The bonding device 30 includes a processing container 100 of which the inside may be sealed, as illustrated in FIG. 4. A side wall of the wafer conveyance region 60 side of the processing container 100 is formed with a carry in/out port 101 for a wafer to be processed W, a supporting wafer S, and a superimposed wafer T. The carry in/out port is installed with an opening/closing shutter (not illustrated).

The inside of the processing container 100 is partitioned into a pre-processing region D1 and a bonding region D2 by an inner wall 102. The above-mentioned carry in/out port 101 is formed in a side wall of the processing container 100 in the pre-processing region D1. In addition, the inner wall 102 is also provided with a carry in/out port 103 for a wafer to be processed W, a supporting wafer S, and a superimposed wafer T.

In the pre-processing region D1, a delivery section 110 is installed to deliver a wafer to be processed W, a supporting wafer S, and a superimposed wafer T from/to the outside of the bonding device 30. The delivery section 110 is arranged adjacent to the carry in/out port 101. In addition, the delivery section 110 may be arranged in a plurality of (e.g., two) tiers in the vertical direction to be capable of delivering two wafers selected from a wafer to be processed W, a supporting wafer S, and a superimposed wafer T at the same time. For example, a wafer to be processed W or a supporting wafer S before bonding may be delivered by one delivery section 110 and a superimposed wafer T after bonding may be delivered by another delivery section 110. Alternatively, a wafer to be processed W before bonding may be delivered by one delivery section 110 and a supporting wafer S before bonding may be delivered by another delivery section 110.

At the negative side in the Y direction, i.e. at the carry in/out port 103 side of the pre-processing region D1, an inverting section 111 configured to invert the front and back surfaces of, for example, a supporting wafer S is installed vertically above the delivery section 110. Meanwhile, the inverting section 111 may adjust the direction of the supporting wafer S in the horizontal direction and adjust the direction of the wafer to be processed W in the horizontal direction, as described below.

At the positive side in the Y direction in the bonding region D2, a conveyance section 112 is installed which is configured to convey a wafer to be processed W, a supporting wafer S, and a superimposed wafer T to the delivery section 110, the inverting section 111, and a bonding section 113 to be described later. The conveyance section 112 is attached to the carry in/out port 103.

At the negative side in the Y direction in the bonding region D2, a bonding section 113 is installed which is configured to press a wafer to be processed W and a supporting wafer S with an adhesive G being interposed therebetween, thereby bonding the wafer to be processed W and the supporting wafer S with each other.

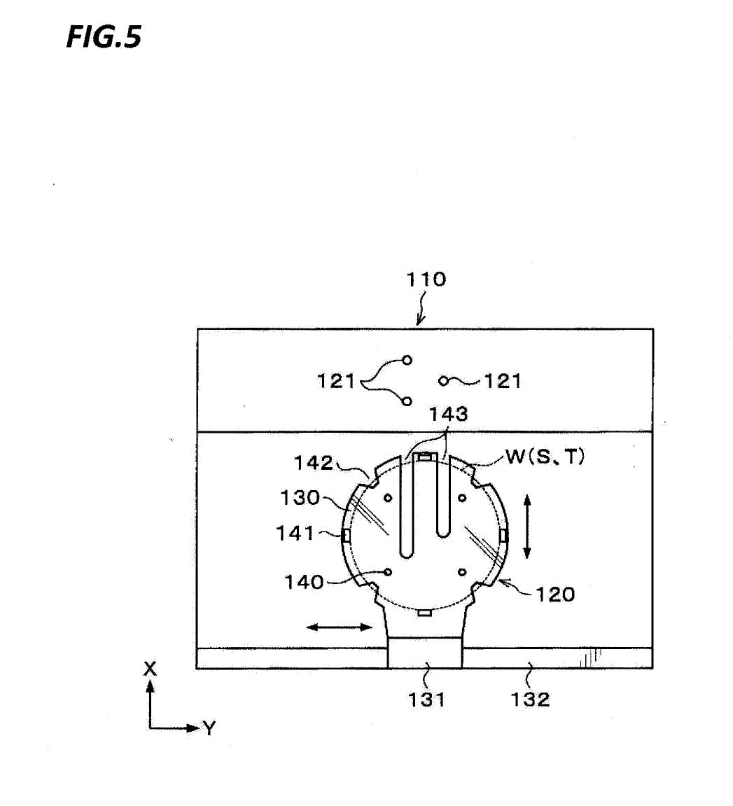

Next, a configuration of the above-described delivery section 110 will be described. As illustrated in FIG. 5, the delivery section 110 includes a delivery arm 120 and wafer support pins 121. The delivery arm 120 may deliver a wafer to be processed W, a supporting wafer S, or a superimposed wafer T between the outside of the bonding device 30, i.e. the wafer conveyance device 61 and wafer support pins 121. The wafer support pins 121 may be installed at a plurality of (e.g., three) locations so as to support the wafer to be processed W, the supporting wafer S, or the superimposed wafer T.

The delivery arm 120 includes an arm unit 130 configured to hold the wafer to be processed W, the supporting wafer S, or the superimposed wafer T, and an arm drive unit 131 which is provided with, for example, a motor. The arm unit 130 has a substantially circular disc shape. The arm drive unit 131 may move the arm unit 130 in the X direction (in the vertical direction in FIG. 5). Further, the arm drive unit 131 is attached to a rail 132 extending in the Y direction (in the horizontal direction in FIG. 5) and configured to be movable on the rail 132. With this configuration, the delivery arm 120 is adapted to be movable in the horizontal direction (in the X direction and Y direction) so that the wafer to be processed W, the supporting wafer S, or the superimposed wafers T may be smoothly delivered between the wafer conveyance device 61 and the wafer support pins 121.

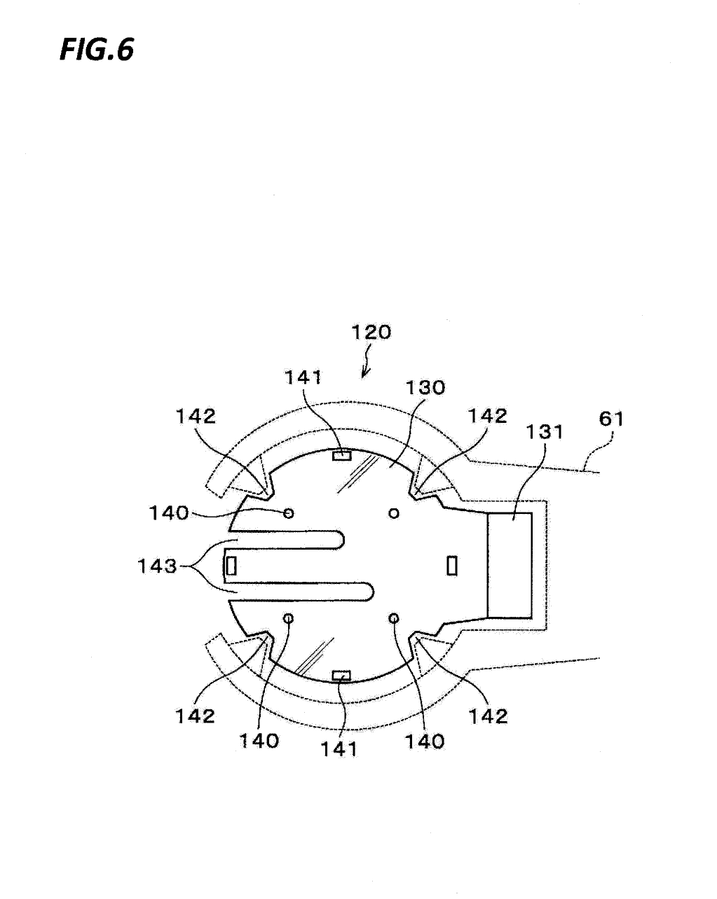

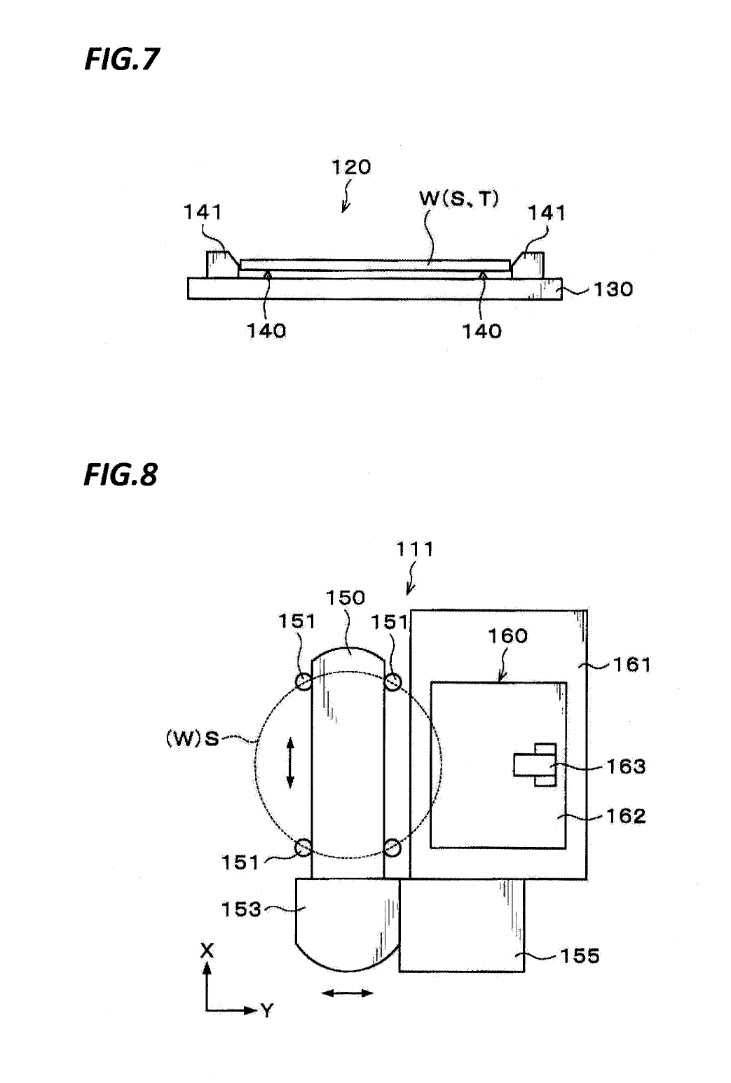

As illustrated in FIGS. 6 and 7, wafer support pins 140 are installed at a plurality of (e.g., four) locations on the arm unit 130 so as to support a wafer to be processed W, a supporting wafer S, or a superimposed wafer T. In addition, on the arm unit 130, a guide 141 is provided so as to position the wafer to be processed W, the supporting wafer S, or the superimposed wafer T supported by the wafer support pins 140. The guide 141 is installed at a plurality of (e.g., four) locations so as to guide the side surface of the wafer to be processed W, the supporting wafer S, or the superimposed wafer T.

As illustrated in FIGS. 5 and 6, cutouts 142 are formed at a plurality of (e.g., four) locations on the outer peripheral portion of the arm unit 130. With the aid of the cutouts 142, the conveyance arm of the wafer conveyance device 61 may be prevented from being interfered with the arm unit 130 when the wafer to be processed W, the supporting wafer S, or the superimposed wafer T is delivered from the conveyance arm of the wafer conveyance device 61 to the delivery arm 120.

The arm unit 130 is formed with two lines of slits 143 along the X direction. The slits 143 are formed to extend from an end face of the wafer support pin 121 side of the arm unit 130 and a position in the vicinity of the center of the arm unit 130. With the aid of the slits 143, the arm unit 130 may be prevented from being interfered with the wafer support pins 121.

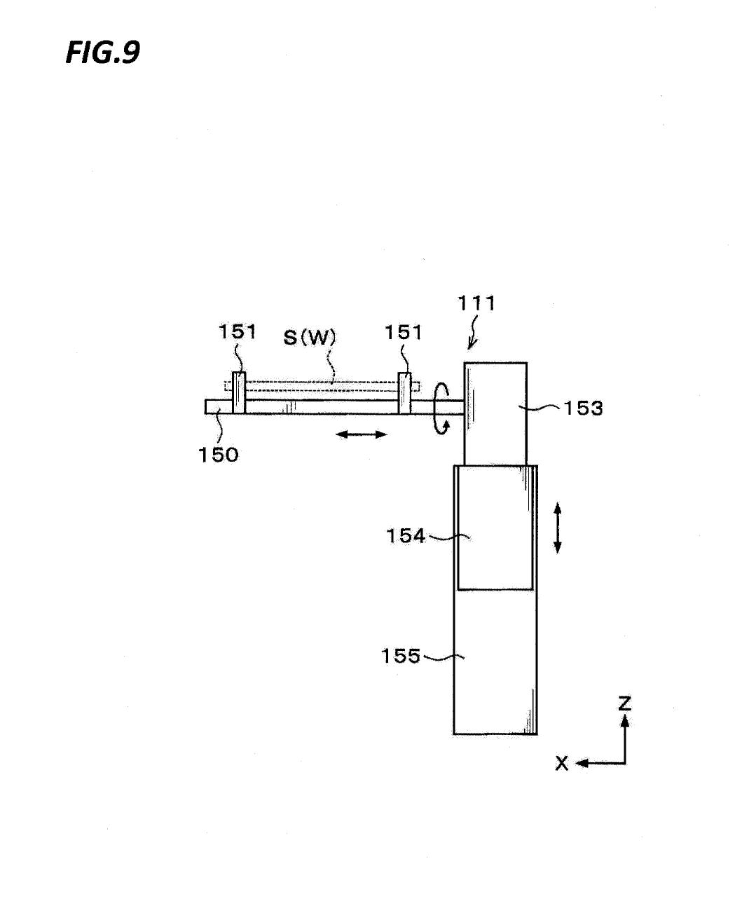

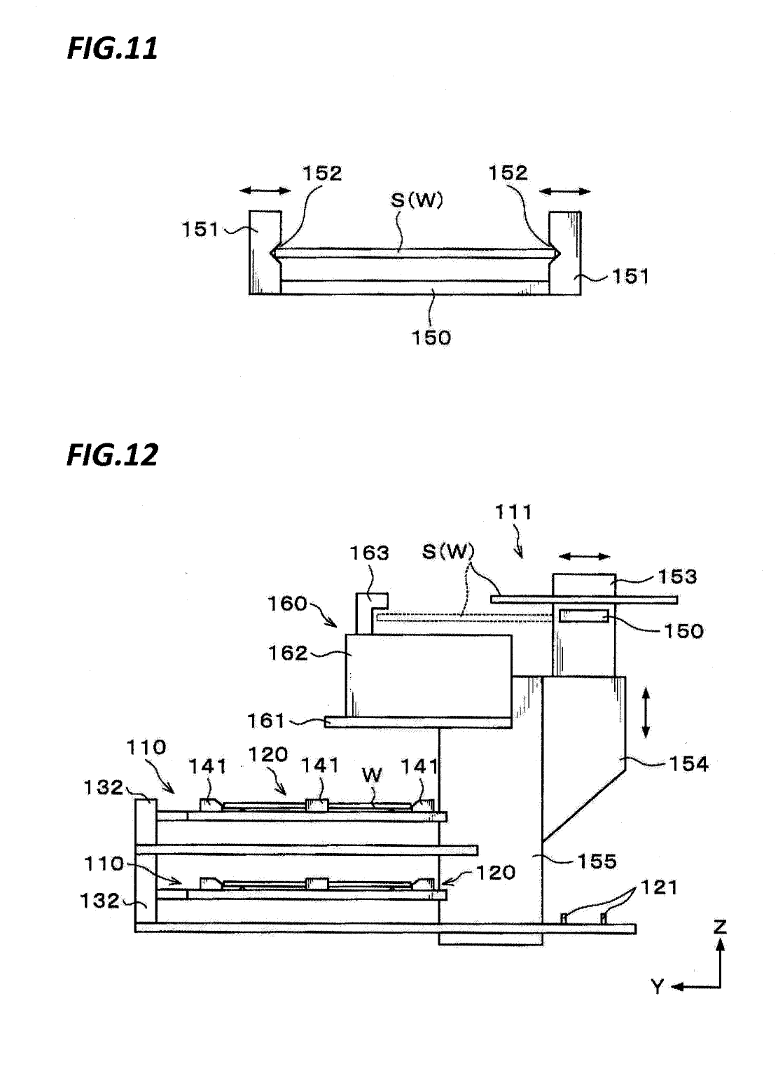

Next, descriptions will be made on a configuration of the above-described inverting section 111. As illustrated in FIGS. 8 to 10, the inverting section 111 includes a holding arm 150 configured to hold a supporting wafer S or a wafer to be processed W. The holding arm 150 extends in the horizontal direction (in the X direction in FIGS. 8 and 9). In addition, the holding arm 150 is provided with holding members 151 at, for example, four locations, as other holding members that hold the supporting wafer S or the wafer to be processed W. As illustrated in FIG. 11, the holding members 151 are configured to be movable in the horizontal direction in relation to the holding arm 150. In addition, a cutout 152 is formed on a side surface of each of the holding members 151 so as to hold the outer peripheral portion of the supporting wafer S or the wafer to be processed W. In addition, the holding members 151 may support the supporting wafer S or the wafer to be processed W therebetween.

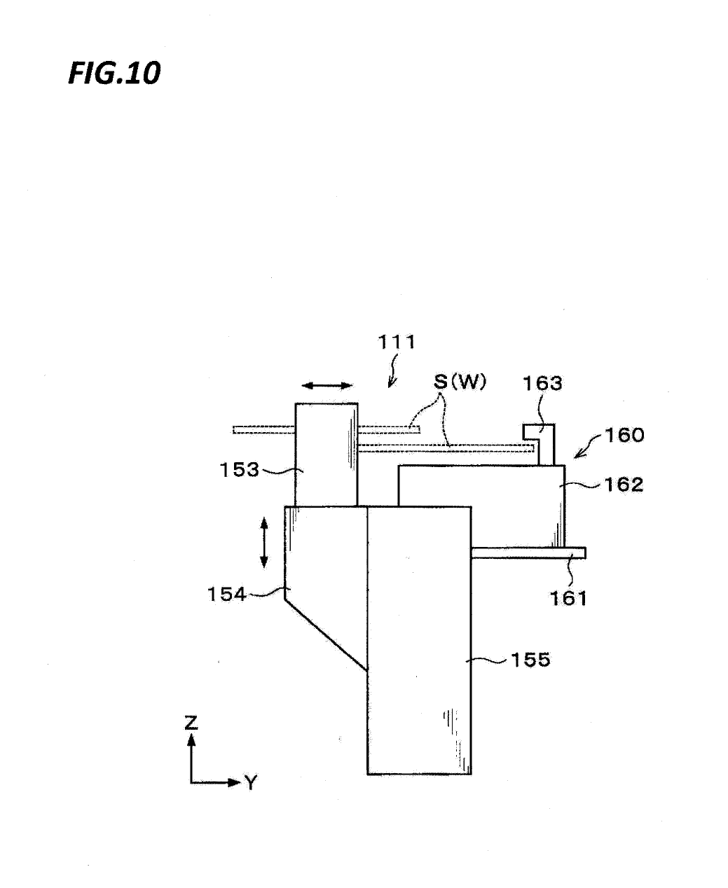

As illustrated in FIGS. 8 to 10, the holding arm 150 is supported by the first drive unit 153 that is provided with, for example, a motor. With the aid of the first drive unit 153, the holding arm 150 may be rotated around a horizontal axis and moved in the horizontal direction (in the X direction in FIGS. 8 and 9 and in the Y direction in FIGS. 8 and 10). Meanwhile, the first drive unit 153 may rotate the holding arm 150 around a vertical axis so as to move the holding arm 150 in the horizontal direction. A second drive unit 154 is installed below the first drive unit 153 in which the second drive unit 154 is provided with, for example, a motor. With the aid of the second drive unit 154, the first drive unit 153 may be moved in the vertical direction along a support pillar 155 extending in the vertical direction. As described above, with the aid of the first drive unit 153 and the second drive unit 154, the supporting wafer S or the wafer to be processed W held by the holding members 151 may be rotated around the horizontal axis and moved in the vertical and horizontal directions. Meanwhile, the first drive unit 153 and the second drive unit 154 constitute the moving mechanism of the present disclosure.

The support pillar 155 supports, through a support plate 161, a position adjusting mechanism 160 configured to adjust the direction of the supporting wafer S or the wafer to be processed W held on the holding members 151 in the horizontal direction. The position adjusting mechanism 160 is installed adjacent to the holding arm 150.

The position adjusting mechanism 160 includes a base 162, and a detection unit 163 configured to detect a notch on the supporting wafer S or the wafer to be processed W. In addition, in the position adjusting mechanism 160, the position of the notch on the supporting wafer S or the wafer to be processed W is detected by the detection unit 163 while the supporting wafer S or the wafer to be processed W held by the holding members 151 is moved in the horizontal direction, so as to adjust the position of the notch, thereby adjusting the direction of the supporting wafer S or the wafer to be processed W in the horizontal direction.

Meanwhile, as illustrated in FIG. 12, delivery sections 110 configured as described above are arranged in two tires in the vertical direction and the inverting section 111 is arranged vertically above the delivery sections 110. That is, the delivery arm 120 of each of the delivery sections 110 is moved in the horizontal direction below the holding arm 150 and the position adjusting mechanism 160 of the inverting section 111. Further, the wafer support pins 121 of the delivery section 110 are arranged below the holding arm 150 of the inverting section 111.

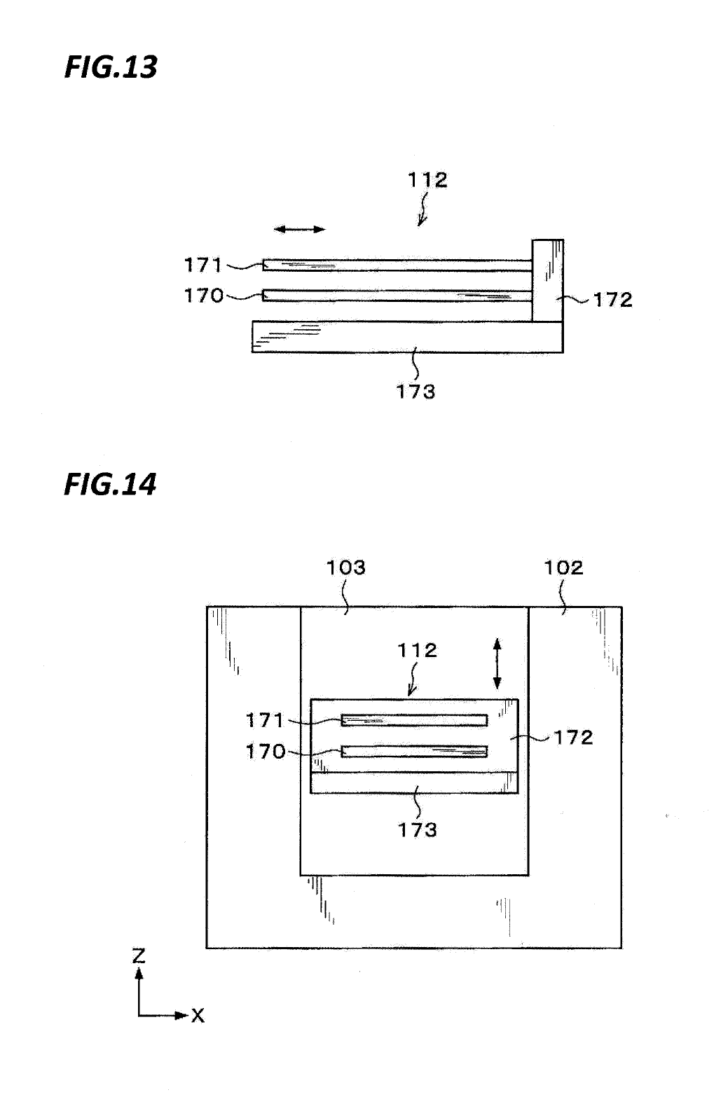

Next, descriptions will be made on a configuration of the conveyance section 112. As illustrated in FIG. 13, the conveyance section 112 includes a plurality of (e.g., two) conveyance arms 170, 171. A first conveyance arm 170 and a second conveyance arm 171 are arranged in this order in two tiers from the lower side in the vertical direction. Meanwhile, the first conveyance arm 170 and the second conveyance arm 171 have different shapes as described later.

An arm drive unit 172 is provided at the base end of the conveyance arms 170, 171, in which the arm drive unit 172 is provided with, for example, a motor. With the aid of the arm drive unit 172, each of the conveyance arms 170, 171 may be moved independently in the horizontal direction. The conveyance arms 170, 171 and the arm drive unit 172 are supported by a base 173.

As illustrated in FIGS. 4 and 14, the conveyance section 112 is installed in the carry in/out port 103 formed in the inner wall 102 of the processing container 100. In addition, the conveyance section 112 may be moved in the vertical direction along the carry in/out port 103 by a drive unit (not illustrated) which is provided with, for example, a motor.

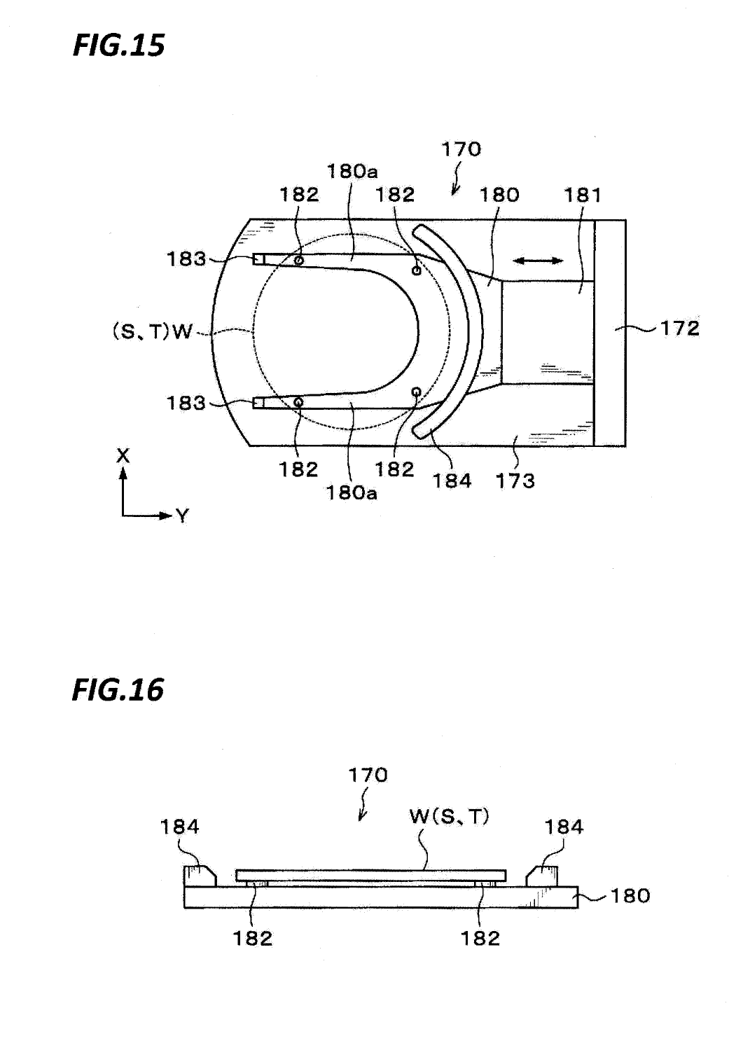

The first conveyance arm 170 holds the back surfaces of a wafer to be processed W, a supporting wafer S, or the superimposed wafer T (the non-bonded surface W_{N} or S_{N} in the wafer to be processed W or the supporting wafer S) so as to convey the wafer to be processed W, the supporting wafer S, or the superimposed wafer T. As illustrated in FIG. 15, the first conveyance arm 170 includes an arm unit 180 of which the front end is branched into two front end portions 180a, 180a, and a support unit 181 which is formed integrally with the arm unit 180 to support the arm unit 180.

As illustrated in FIGS. 15 and 16, O-rings 182 made of a resin as the first holding members are provided on the arm unit 180 at a plurality of (e.g., four) locations. The O-rings 182 come in contact with the back surface of a wafer to be processed W, a supporting wafer S, or a superimposed wafer T, and the O-rings 182 hold the back surface of the wafer to be processed W, the supporting wafer S, or the superimposed wafer T by frictional force between the O-rings 182 and the back surface of the wafer to be processed W, the supporting wafer S, or the superimposed wafer T. In addition, the first conveyance arm 170 may hold the wafer to be processed W, the supporting wafer S, or the superimposed wafer T horizontally on the O-rings 182.

In addition, guide members 183, 184 are provided on the arm unit 180 at the outside of the wafer to be processed W, the supporting wafer S, or the superimposed wafer T held on the O-rings 182. The first guide member 183 is provided at the front end of each of the front end portions 180a of the arm unit 180. The second guide member 184 is formed in a circular arc shape according to the outer peripheral portion of the wafer to be processed W, the supporting wafer S, or the superimposed wafer T and installed at the support unit 181 side. With the aid of the guide members 183, 184, the wafer to be processed W, the supporting wafer S, or the superimposed wafer T may be prevented from slipping out or sliding down from the first conveyance arm 170. Meanwhile, when the wafer to be processed W, the supporting wafer S, or the superimposed wafer T is held on the O-rings 182 at a proper position, the wafer to be processed W, the supporting wafer S, or the superimposed wafer T does not come in contact with the guide members 183, 184.

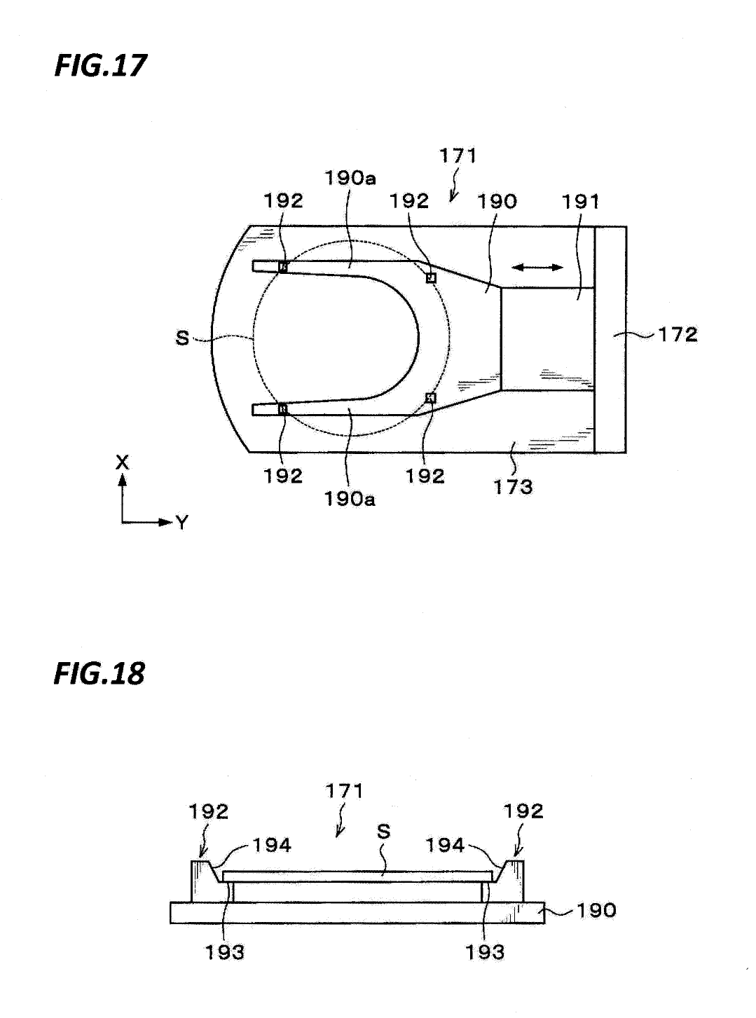

The second conveyance arm 171 holds the front surface of, for example, the supporting wafer S, that is, the outer peripheral portion of the bonded surface S_{J} so as to convey the supporting wafer S. That is, the second conveyance arm 171 holds the outer peripheral portion of the bonded surface S_{J} of the supporting wafer S of which the front and back surfaces have been inverted in the inverting section 111 to convey the supporting wafer S. As illustrated in FIG. 17, the second conveyance arm 171 includes an arm unit 190 of which the front end is branched into two front end portions 190a, 190a and a support unit 191 which is formed integrally with the arm unit 190 so as to further support the arm unit 190.

As illustrated in FIGS. 17 and 18, second holding members 192 are provided on the arm unit 190 at a plurality of (e.g., four) locations. Each of the second holding members 192 includes a placement portion 193 on which the outer peripheral portion of the bonded surface S_{J} of the supporting wafer S is placed, and a tapered portion 194 that extends upward from the placement portion 193 and has an inner surface which is enlarged in a taper shape from the bottom side toward the top side. The placement portion 193 holds the outer peripheral portion of the supporting wafer S within, for example, 1 mm from the outer peripheral edge of the supporting wafer S. Further, since the inner surface of the tapered portion 194 is enlarged in a taper shape from the bottom side toward the top side, the supporting wafer S is smoothly guided and positioned by the tapered portion 194 and held on the placement portion 193 to a given position in the horizontal direction, even if the supporting wafer S delivered to the second holding members 192 is misaligned, for example. In addition, the second conveyance arm 171 may hold the supporting wafer S horizontally on the second holding member 192.

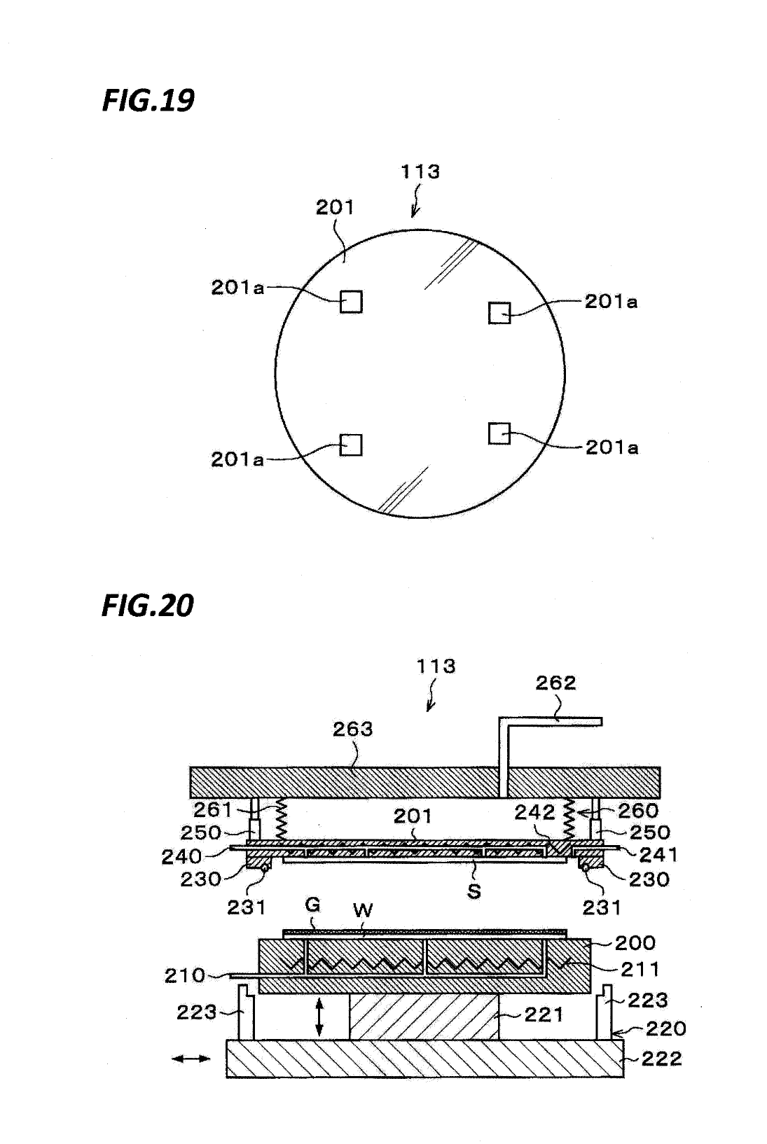

Meanwhile, as illustrated in FIG. 19, the second holding unit 201 of the bonding section 113 to be described later is formed with cutouts 201a at, for example, four locations. With the aid of the cutouts 201a, the second holding members 192 of the second conveyance arm 171 may be prevented from being interfered with the second holding unit 201 when the supporting wafer S is delivered from the second conveyance arm 171 to the second holding unit 201.

Next, descriptions will be made on a configuration of the above-described bonding section 113. As illustrated in FIG. 20, the bonding section 113 includes a first holding unit 200 configured to hold a wafer to be processed W placed on the top surface thereof, and a second holding unit 201 configured to attract and hold a supporting wafer S at the bottom side of the supporting wafer S. The first holding unit 200 is installed below the second holding unit 201 and arranged to be opposite to the second holding unit 201. That is, the wafer to be processed W held on the first holding unit 200 and the supporting wafer S held on the second holding unit 201 are arranged to be opposite to each other.

In the inside of the first holding unit 200, a suction tube 210 is installed so as to attract and hold the wafer to be processed W. The suction tube 210 is connected to a negative pressure generating device (not illustrated) such as, for example, a vacuum pump. Meanwhile, as for the first holding unit 200, a material having a strength that is not deformed even if a load is applied thereto by a pressing mechanism 260 to be described later, for example, a ceramic such as a silicon carbonate ceramic or an aluminum nitride ceramic, may be used.

In addition, a heating mechanism 211 configured to heat the wafer to be processed W is installed inside the first holding unit 200. As for the heating mechanism 211, for example, a heater is used.

Under the first holding unit 200, a moving mechanism 220 is installed which is configured to move the first holding unit 200 and a wafer to be processed W in the vertical direction and the horizontal direction. The moving mechanism 220 may move the first holding unit 200 three-dimensionally, for example, with a ±1 μm precision. The moving mechanism 220 includes a vertical moving unit 221 configured to move the first holding unit 200 in the vertical direction, and a horizontal moving unit 222 configured to move the first holding unit 200 in the horizontal direction. Each of the vertical moving unit 221 and the horizontal moving unit 222 includes, for example, a ball screw (not illustrated), and a motor (not illustrated) that rotates the ball screw.

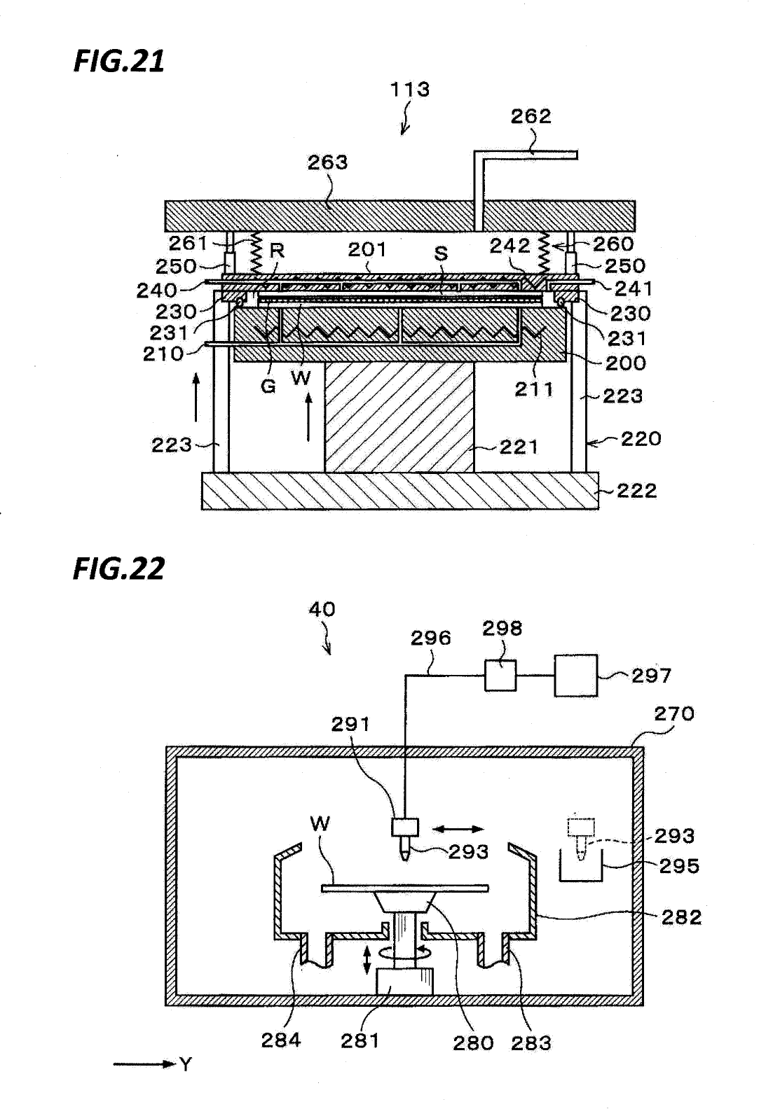

Support members 223, which are vertically extendable and retractable, are installed on the horizontal moving unit 222. The support members 223 are installed at, for example, three locations, outside the first holding unit 200. Further, as illustrated in FIG. 21, the support members 223 may support a protrusion 230 formed on the bottom surface of the outer peripheral portion of the second holding unit 201 to protrude downwardly.

In the moving mechanism 220, a wafer to be processed W on the first holding unit 200 may be aligned in the horizontal direction, and, as illustrated in FIG. 21, the first holding unit 200 may be lifted so as to form a bonding space R for bonding a wafer to be processed W and a supporting wafer S with each other. The bonding space R is surrounded by the first holding unit 200, the second holding unit 201, and the protrusion 230. When forming the bonding space R, the height of the support members 223 may be adjusted so as to adjust the vertical distance between the wafer to be processed W and the supporting wafer S in the bonding space R.

Under the first holding unit 200, a lift pin (not illustrated) is installed so as to support and lift the wafer to be processed W or the superimposed wafer T at the bottom side. The lift pin is configured to be inserted through a through hole (not illustrated) formed in the first holding unit 200 so that the lift pin may protrude from the top surface of the first holding unit 200.

As for the second holding unit 201, for example, aluminum may be used to function as an elastic body. In addition, as will be described later, the second holding unit 201 is configured to be flexed at a portion, for example, the central portion thereof, may be flexed when a predetermined pressure, for example, 0.7 atmospheric pressure (=0.07 MPa), is applied to the front side of the second holding unit 201.

As illustrated in FIG. 20, on the bottom surface of the outer peripheral portion of the second holding unit 201, the above-mentioned protrusion 230 is formed to protrude downwardly from the bottom surface of the outer peripheral portion. The protrusion 230 is formed along the outer peripheral portion of the second holding unit 201. Meanwhile, the protrusion 230 may be formed integrally with the second holding unit 201.

The bottom surface of the protrusion 230 is provided with a seal material 231 so as to maintain hermeticity of the bonding space R. The seal material 231 is formed in an annular shape in a groove formed on the bottom surface of the protrusion 230 and, for example, an O-ring is used. In addition, the seal material 231 has elasticity. Meanwhile, the seal material 231 is not limited to the present exemplary embodiment as long as it is a part having a seal function.

A suction tube 240 is installed inside the second holding unit 201 to suck and hold the supporting wafer S. The suction tube 240 is connected to a negative pressure generating device (not illustrated) such as, for example, a vacuum pump.

In addition, an intake tube 241 is installed inside the second holding unit 201 so as to suck the atmosphere of the bonding space R. One end of the intake tube 241 is opened at a place where the supporting wafer S is not held on the bottom of the second holding unit 201. Further, the other end of the intake tube 241 is connected to a negative pressure generating device (not illustrated) such as, for example, a vacuum pump.

In addition, a heating mechanism 242 configured to heat the supporting wafer S is provided inside the second holding unit 201. As for the heating mechanism 242, for example, a heater is used.

On the top of the second holding unit 201, a pressing mechanism 260 is installed to press downward the support members 250 that support the second holding unit 201 and the second holding unit 201. The pressing mechanism 260 includes a pressure container 261 configured to enclose a wafer to be processed W and a supporting wafer S, a fluid supply tube 262 configured to supply a fluid such as, for example, compressed air, to the inside of the pressure container 261. In addition, the support members 250 are configured to be extendible and retractable in the vertical direction and installed at, for example, at three locations outside the pressure container 261.

The pressure container 261 is made up of, for example, a bellows which is extendible and retractable in the vertical direction and formed of, for example, a stainless steel. The bottom surface of the pressure container 261 is in contact with the top surface of the second holding unit 201 and the top surface of the pressure container 261 is in contact with the bottom surface of a support plate 263 installed above the second holding unit 201. The fluid supply tube 262 is connected to the pressure container 261 at one end thereof and to a fluid supply source (not illustrated) at the other end. In addition, when the fluid is supplied to the pressure container 261 from the fluid supply tube 262, the pressure container 261 is extended. In this event, since the top surface of the pressure container 261 and the bottom surface of the support plate 263 are in contact with each other, the pressure container 261 may press downward the second holding unit 201 installed on the bottom surface of the pressure container 261, upon being extended downward. In addition, the inside of the pressure container 261 is pressurized by the fluid at that time, the pressure container 261 may uniformly press the second holding unit 201 in the second holding unit plane. The control of load at the time of pressing the second holding unit 201 may be executed by adjusting the pressure of the compressed air supplied to the pressure container 261. Meanwhile, it is desirable that the support plate 263 is made up of a member having a strength that is not deformed even if the support plate 263 receives a reaction force of the load applied to the second holding unit 201 by the pressing mechanism 260. Meanwhile, the top surface of the pressure container 261 may be contacted with the ceiling of the processing container 100 while omitting the support plate 263 of the present exemplary embodiment.

Meanwhile, since the configurations of the bonding devices 31 to 33 are the same with that of the bonding device 30 as described above, the descriptions on the bonding devices 31 to 33 will be omitted.

Next, descriptions will be made on a configuration of the above-described coating device 40. As described in FIG. 22, the coating device 40 includes a processing container 270 capable of sealing the inside thereof. The side wall of the wafer conveyance region 60 side of the processing container 270 is formed with a carry in/out port (not illustrated) for a wafer to be processed W and an opening/closing shutter (not illustrated) is installed in the carry in/out port.

A spin chuck 280 configured to hold and rotate a wafer to be processed W is installed at a central portion inside the processing container 270. The spin chuck 280 has a horizontal top surface which is formed with a suction port (not illustrated) configured to suck, for example, a wafer to be processed W. By the suction from the suction port, the wafer to be processed W may be sucked to and held on the spin chuck 280.

Under the spin chuck 280, a chuck drive unit 281 which is provided with, for example, a motor, is installed. The spin chuck 280 may be rotated at a predetermined speed by the chuck drive unit 281. Further, the chuck drive unit 281 is equipped with a lift drive source (not illustrated) such as, for example, a cylinder, so that the spin chuck 280 may be lifted.

Around the spin chuck 280, a cup 282 is installed to receive and recover a liquid scattered or dropped from a wafer to be processed W. A discharge tube 283 configured to discharge the recovered liquid and an exhaust tube 284 configured to evacuate the atmosphere inside the cup 282 to a vacuum state are connected to the bottom of the cup 282.

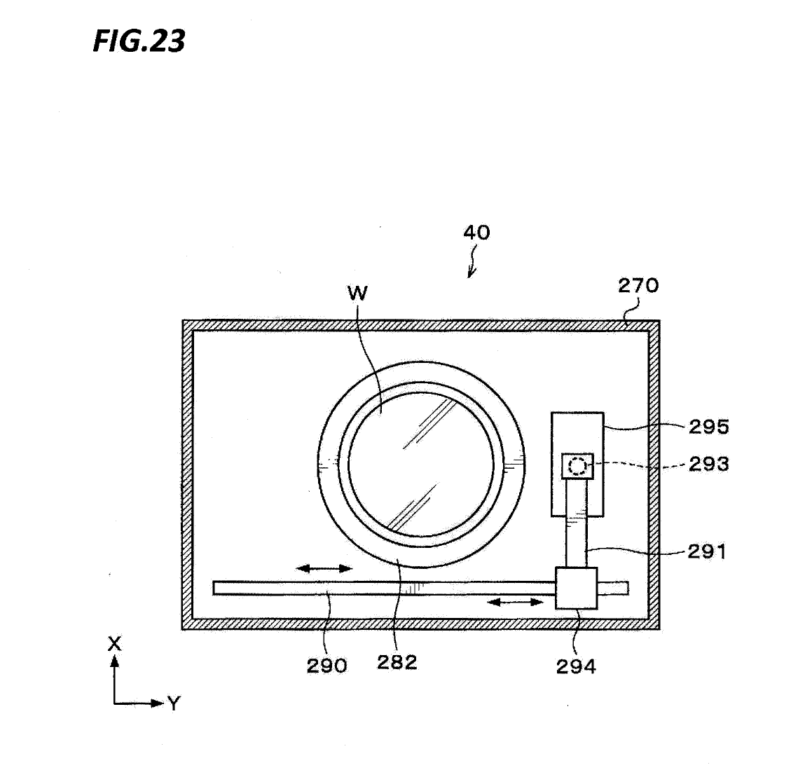

As illustrated in FIG. 23, a rail 290 extending along the Y direction (in the horizontal direction in FIG. 23) is formed at the negative side in the X direction (in the vertical direction) of the cup 282. The rail 290 is formed to extend from the outside of the cup 282 at the negative side in the Y direction (at the left side in FIG. 23) to the outside of the cup 282 at the positive side in the Y direction (at the right side in FIG. 23). An arm 291 is attached to the rail 290.

As illustrated in FIGS. 22 and 23, the arm 291 supports an adhesive nozzle 293 configured to supply an adhesive G in a liquid state to a wafer to be processed W. The arm 291 may be moved on the rail by a nozzle drive unit 294 as illustrated in FIG. 23. Accordingly, the adhesive nozzle 293 may be moved from a standby section 295 installed at the outside of the cup 282 at the positive side in the Y direction to a location above the center of the wafer to be processed W within the cup 282 and also moved from the location above the wafer to be processed W in the radial direction of the wafer to be processed W. In addition, the arm 291 may be lifted by the nozzle drive unit 294 and may adjust the height of the adhesive nozzle 293.

As illustrated in FIG. 22, the adhesive nozzle 293 is connected with a supply tube 296 configured to supply the adhesive G to the adhesive nozzle 293. The supply tube 296 is communicated with an adhesive supply source 297 that stores the adhesive G therein. In addition, the supply tube 296 is provided with a supply device group 298 that includes, for example, a valve or a flow control unit that controls the flow of adhesive G.

Meanwhile, under the spin chuck 280, a backside rinse nozzle (not illustrated) configured to inject a cleaning liquid toward the back surface of a wafer to be processed W, i.e. the non-bonded surface W_{N}, may be provided. With the aid of the cleaning liquid of the backside rinse nozzle, the non-bonded surface W_{N} of the wafer to be processed W and the outer peripheral portion of the wafer to be processed W are cleaned.

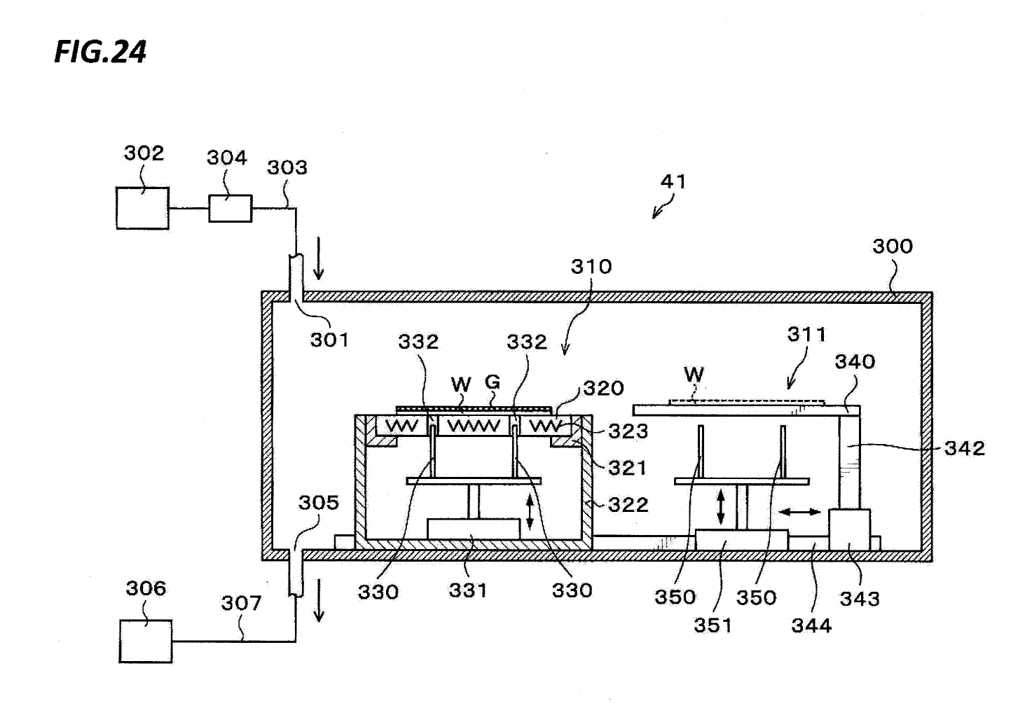

Next, descriptions will be made on configurations of the heat treatment devices 41 to 46 as described above. As illustrated in FIG. 24, the heat treatment device 41 is includes a processing container 300 of which the inside may be closed. A side wall of the wafer conveyance region 60 side of the processing container 300 is formed with a carry in/out port (not illustrated) for a wafer to be processed W, and an opening/closing shutter (not illustrated) is installed in the carry in/out port.

The ceiling of the processing container 300 is formed with a gas supply port 301 configured to supply an inert gas such as, for example, nitrogen gas, to the inside of the processing container 300. The gas supply port 301 is connected with a gas supply tube 303 which is communicated with a gas supply source 302. The gas supply tube 303 is provided with a supply device group 304 that includes, for example, a valve or a flow control unit that controls the flow of the inert gas.

The bottom of the processing container 300 is formed with an intake port 305 configured to suck the atmosphere of the inside of the processing container 300. The intake port 305 is connected with an intake tube 307 that is communicated with a negative pressure generating device 306 such as, for example, a vacuum pump.

Within the processing container 300, a heating section 310 configured to perform a heating processing on a wafer to be processed W and a temperature control section 311 configured to control the temperature of the wafer to be processed W are provided. The heating section 310 and the temperature control section 311 are arranged in parallel to each other in the Y direction.

The heating section 310 is provided with an annular holding member 321 configured to accommodate a heat plate 320 so as to hold the outer peripheral portion of the heat plate 320, and a support ring 322 of a substantially cylindrical shape that surrounds the outer peripheral portion of the holding member 321. The heat plate 320 is formed substantially in a disc shape with a thickness and configured to heat a wafer to be processed W placed thereon. Further, the heat plate 320 includes, for example, a heater 323 embedded therein. The heating temperature of the heat plate 320 may be controlled by, for example, a control unit 360 (see, e.g., FIG. 1) so as to heat the wafer to be processed W placed on the heat plate 320 to a predetermined temperature.

Under the heat plate 320, a plurality of (e.g., three) lift pins 330 configured to support and lift a wafer to be processed W from the bottom side are provided. The lift pins 330 may be moved up and down by a lift drive unit 331. In the vicinity of the central portion of the heat plate 320, through holes 332 that extend through the heat plate 320 in the thickness direction are formed at, for example, three locations. In addition, the lift pins 330 are adapted to protrude from the top surface of the heat plate 320 through the through holes 332.

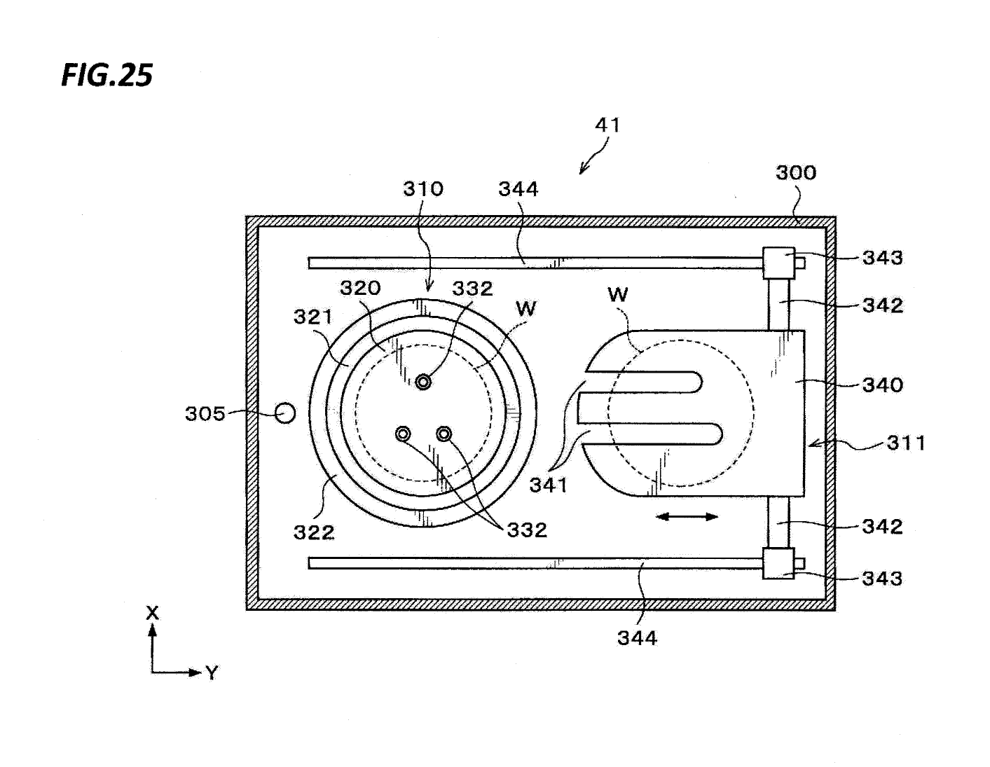

The temperature control section 311 includes a temperature control plate 340. As illustrated in FIG. 25, the temperature control plate 340 has a substantially rectangular flat shape and an end face of the heat plate 320 side is curved in a circular shape. The temperature control plate 340 is formed with two lines of slits 341 along the Y direction. The slits 341 are formed to extend from an end face of the heat plate 320 side of the temperature control plate 340 to a position in the vicinity of the central portion of the temperature control plate 340. With the aid of the slits 341, the temperature control plate 340 may be prevented from being interfered with the lift pins 330 of the heating section 310 and lift pins 350 of the temperature control section 311 to be described later. Further, the temperature control plate 340 includes a temperature control member (not illustrated) such as, for example, a Peltier element, which is embedded in the temperature control plate 340. The cooling temperature of the temperature control plate 340 is controlled by, for example, the control unit 360 (see, e.g., FIG. 1) so that the wafer to be processed W placed on the temperature control plate 340 is cooled to a predetermined temperature.

As illustrated in FIG. 24, the temperature control plate 340 is supported on the support arm 342. A drive unit 343 is attached to the support arm 342. The drive unit 343 is attached to a rail 344 extending in the Y direction. The rail 344 extends from the temperature control section 311 to the heating section 310. With the aid of the drive unit 343, the temperature control plate 340 is adapted to be movable between the heating section 310 and the temperature control section 311 along the rail 344.

Under the temperature control plate 340, a plurality of (e.g., three) lift pins 350 configured to support and lift a wafer to be processed W from the bottom side are provided. The lift pins 350 may be moved up and down by the lift drive unit 351. In addition, the lift pins 350 are adapted to protrude from the top surface of the temperature control plate 340 through the slits 341.

Meanwhile, because the configuration of the heat treatment devices 42 to 46 is the same as that of the heat treatment device 41 as described above, the descriptions thereof will be omitted.

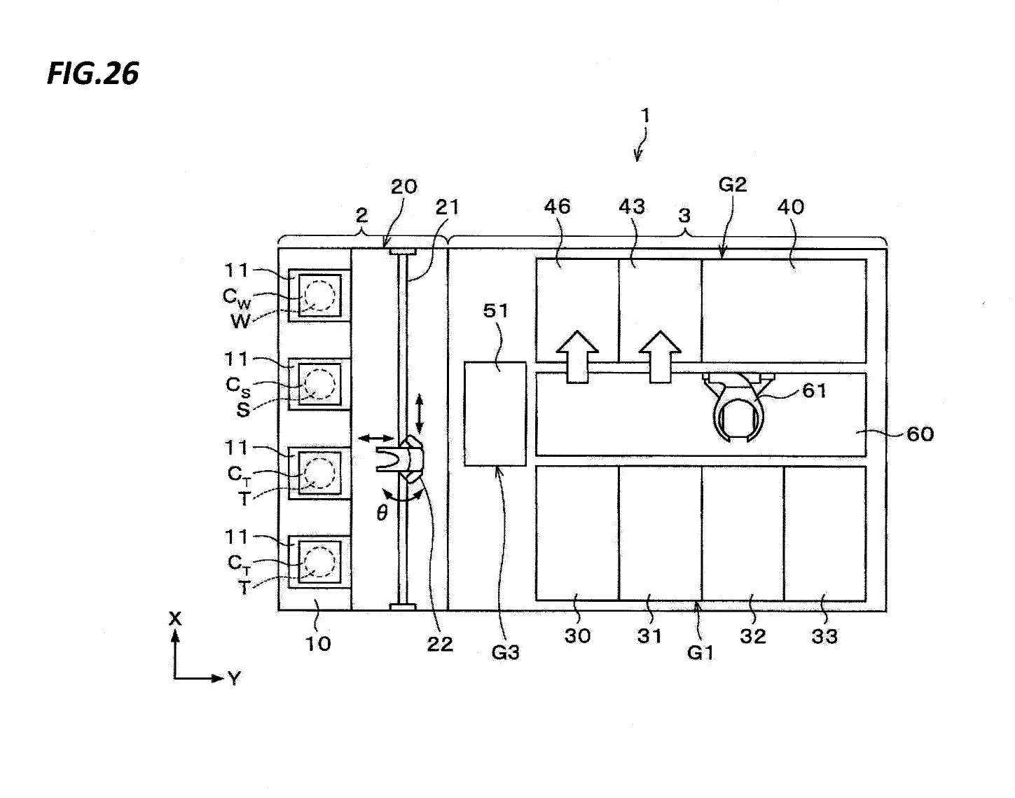

In addition, when a bonding processing is performed on a wafer to be processed W and a supporting wafer S in the bonding system 1, the pressure within each of the above-described heat treatment devices 41 to 46 is set to a negative pressure with respect to the wafer conveyance region 60. For this reason, when the opening/closing shutter of the processing container 300 of each of the heat treatment devices 41 to 46 is opened, air flow directing from the wafer conveyance region 60 to each of the heat treatment devices 41 to 46 is generated as illustrated in arrows in FIG. 26.

In the bonding system 1 as described above, the control unit 360 is provided as illustrated in FIG. 1. The control unit 360 is, for example, a computer which includes a program storage unit (not illustrated). In the program storage unit, programs configured to control the processings of a wafer to be processed W, a supporting wafer S, and a superimposed wafer T in the bonding system 1 are stored. In addition, the program storage unit is also stored with programs configured to control the operations of the drive systems of various processing devices or conveyance devices as described above so that a bonding processing to be described later may be executed in the boding system 1. Meanwhile, the programs may be those that have been stored in a computer-readable storage medium H such as, for example, a computer-readable hard disc (HD), a flexible disc (FD), a compact disc (CD), a magnetic optical disc (MO) or a memory card and installed to the control unit 360 from the storage medium H.

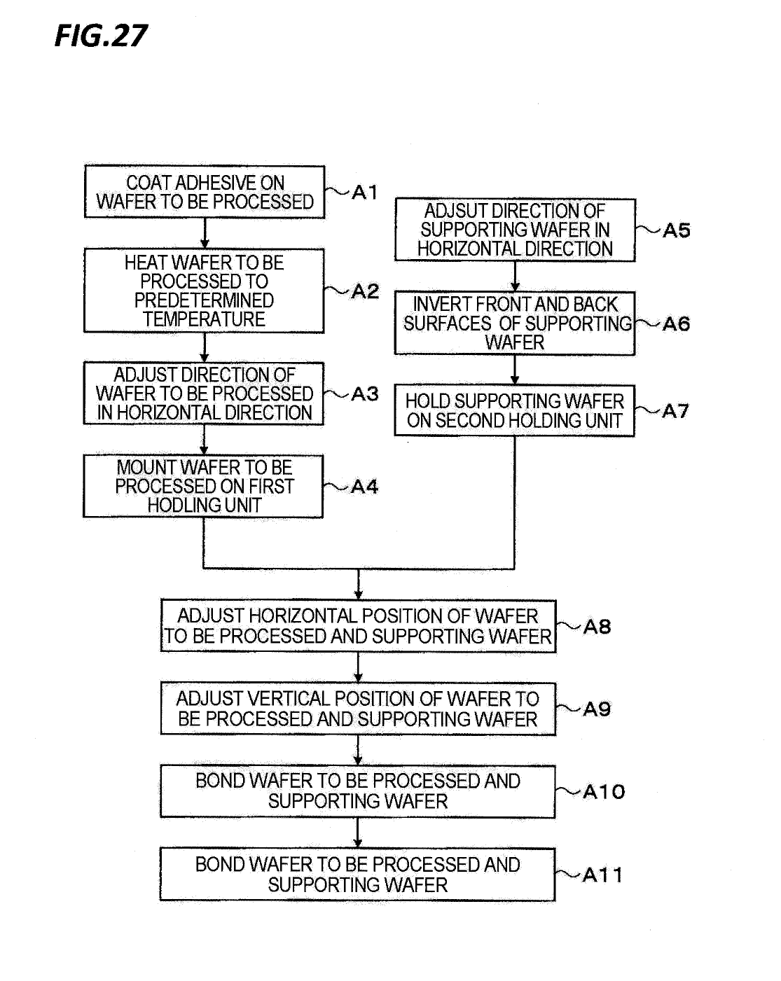

Next, descriptions will be made on a method of bonding a wafer to be processed W and a supporting wafer S using the bonding system 1 configured as described above. FIG. 27 is a flowchart illustrating an example of a main process in such bonding.

First, a cassette C_{W} that accommodates a plurality of wafers to be processed W, a cassette C_{S} that accommodates a plurality of supporting wafers S, and an empty cassette C_{T} are respectively placed on predetermined cassette mounting plates 11 in the carry in/out station 2. Then, a wafer to be processed W within the cassette C_{W} is taken out by the wafer conveyance device 22 and conveyed to the transition device 50 of the third processing block G3 of the bonding processing station 3. In this event, the wafer to be processed W is conveyed in a state where its non-bonded surface W_{N} faces downward.

Subsequently, the wafer to be processed W is conveyed to the coating device 40 by the wafer conveyance device 61. The wafer to be processed W carried into the coating device 40 is delivered to the spin chuck 280 from the wafer conveyance device 61 and sucked and held by the spin chuck 280. In this event, the non-bonded surface W_{N} of the wafer to be processed W is sucked and held.

Subsequently, the adhesive nozzle 293 of the standby section 295 is moved above the central portion of the wafer to be processed W by the arm 291. Then, the adhesive G is supplied from the adhesive nozzle 293 to the bonded surface W_{J} of the wafer to be processed W while rotating the wafer to be processed W by the spin chuck 280. The supplied adhesive G is diffused over the entire bonded surface W_{J} of the wafer to be processed W by centrifugal force so that the adhesive G is coated on the bonded surface W_{J} of the wafer to be processed W (process A1 in FIG. 27).

Subsequently, the wafer to be processed W is conveyed to the heat treatment device 41 by the wafer conveyance device 61. At this time, the inside of the heat treatment device 41 remains in an inert gas atmosphere. When the wafer to be processed W is carried into the heat treatment device 41, a superimposed wafer T is delivered to the lift pins 350 which have been moved up in advance from the wafer conveyance device 61 and on standby. Subsequently, the lift pins 350 are moved down and the wafer to be processed W is placed on the temperature control plate 340.

Then, the temperature control plate 340 is moved along the rail 344 to a position above the heat plate 320 by the drive unit 343 and the wafer to be processed W is delivered to the lift pins 330 which have been moved up in advance and on standby. Then, the lift pins 330 are moved down so that the wafer to be processed W is placed on the heat plate 320. Then, the wafer to be processed W on the heat plate 320 is heated to a predetermined temperature in the range of, for example, 100° C. to 250° C. (process A2 in FIG. 27). By heating using the heat plate 320, the adhesive G on the wafer to be processed W is heated to be cured.

Then, the lift pins 330 are moved up and the temperature control plate 340 is moved to a position above the heat plate 320. Subsequently, the wafer to be processed W is delivered to the temperature control plate 340 from the lift pins 330 and the temperature control plate 340 moves to the wafer conveyance region 60. During the movement of the temperature control plate 340, the temperature of the wafer to be processed W is controlled to a predetermined temperature.

The wafer to be processed W which has been subjected to the heat treatment by the heat treatment device 41 is conveyed to the bonding device 30 by the wafer conveyance device 61. The wafer to be processed W conveyed to the bonding device 30 is delivered to the delivery arm 120 of the delivery section 110 from the wafer conveyance device 61, and then, delivered to the wafer support pins 121 from the delivery arm 120. Then, the wafer to be processed W is conveyed from the wafer support pins 121 to the inverting section 111 by the first conveyance arm 170 of the conveyance section 112.

The wafer to be processed W conveyed to the inverting section 111 is held by the holding member 151 and moved to the position adjusting mechanism 160. In addition, in the position adjusting mechanism 160, the position of the notch of the wafer to be processed W is adjusted so that the direction of the wafer to be processed W in the horizontal direction (process A3 in FIG. 27).

Then, the wafer to be processed W is conveyed from the inverting section 111 to the bonding section 113 by the first conveyance arm 170 of the conveyance section 112. The wafer to be processed W conveyed to the bonding section 113 is placed on the first holding unit 200 (process A4 in FIG. 27). On the first holding unit 200, the wafer to be processed W is placed in a state where the bonded surface W_{J} of the wafer to be processed W faces upward, that is, the adhesive G faces upward.

While the processings of processes A1 to A4 are performed on the wafer to be processed W, a processing is performed on a supporting wafer S following the wafer to be processed W. The supporting wafer S is conveyed to the bonding device 30 by the wafer conveyance device 61. Meanwhile, because the process of conveying the supporting wafer S to the bonding device 30 is the same as that in the above-described process, the description thereof will be omitted.

The supporting wafer S delivered to the bonding device 30 is delivered from the wafer conveyance device 61 to the delivery arm 120 of the delivery section 110 and then, delivered from the delivery arm 120 to the wafer support pin 121. Then, the supporting wafer S is conveyed from the wafer support pin 121 to the inverting section 111 by the first conveyance arm 170 of the conveyance section 112.

The supporting wafer S conveyed to the inverting section 111 is held by the holding members 151 and moved to the position adjusting mechanism 160. Then, in the position adjusting mechanism 160, the position of the notch of the supporting wafer S is adjusted so that the direction of the supporting wafer S in the horizontal direction is adjusted (process A5 in FIG. 27). After the direction in the horizontal direction is adjusted, the supporting wafer S is moved from the position adjusting mechanism 160 in the horizontal direction, moved upward in the vertical direction, and then, the front and back surfaces thereof are inverted (process A6 in FIG. 27). That is, the bonded surface S_{J} of the supporting wafer S faces downward.

Then, the supporting wafer S is moved downward in the vertical direction and then, conveyed from the inverting section 111 to the bonding section 113 by the second conveyance arm 171 of the conveyance section 112. At this time, because the second conveyance arm 171 holds only the peripheral portion of the bonded surface S_{J} of the supporting wafer S, the bonded surface S_{J} is not polluted by, for example, particles adhered to the second conveyance arm 171. The supporting wafer S conveyed to the bonding section 113 is sucked and held by the second holding unit 201 (process A7 in FIG. 27). On the second holding unit 201, the supporting wafer S is held in a state where the bonded surface S_{J} thereof faces downward.

In the bonding device 30, when the wafer to be processed W and the supporting wafer S are held on the first holding unit 200 and the second holding unit 201, respectively, the position of the first holding unit 200 in the horizontal direction is adjusted by the moving mechanism 220 such that the wafer to be processed W is positioned opposite to the supporting wafer S (process A8 of FIG. 27). Meanwhile, at this time, the pressure between the second holding unit 201 and the supporting wafer S is, for example, 0.1 atmosphere (=0.01 MPa). Further, the pressure applied to the top surface of the second holding unit 201 is 1.0 atmosphere (=0.1 MPa) which is the atmospheric pressure. In order to maintain the atmospheric pressure applied to the top surface of the second holding unit 201, the pressure within the pressure container 261 of the pressing mechanism 260 may be set to the atmospheric pressure and a gap may be formed between the top surface of the second holding unit 201 and the pressure container 261.

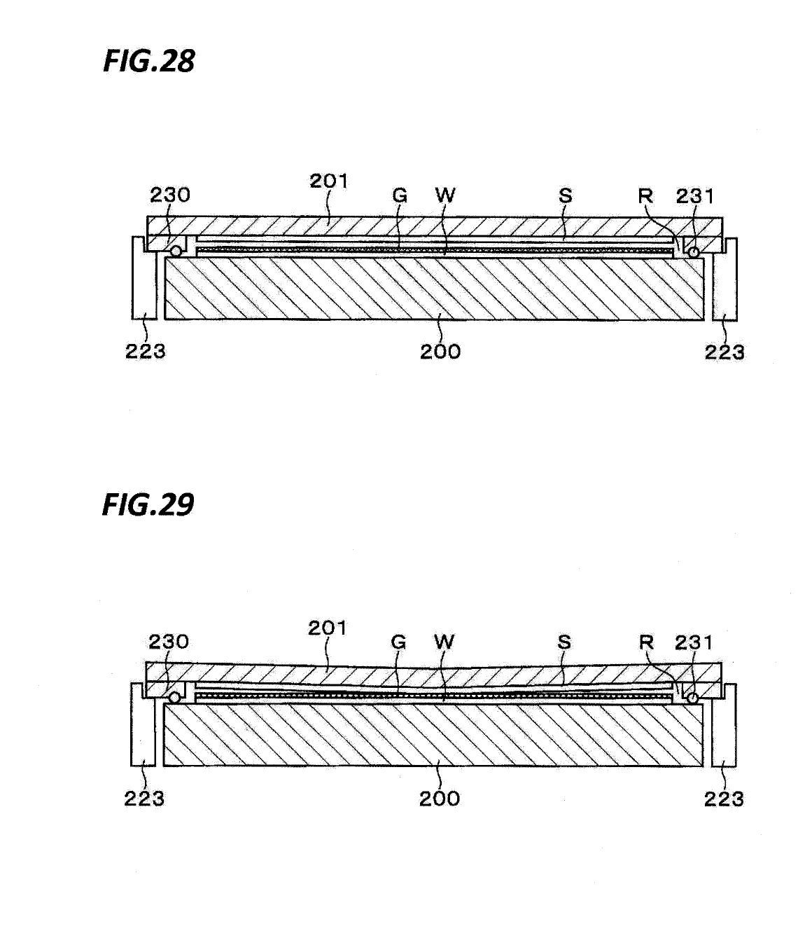

Subsequently, as illustrated in FIG. 28, the first holding unit 200 is moved up by the moving mechanism 220 and the support members 223 are extended so that the second holding unit 201 is supported on the support members 223. At this time, when the height of the support member 223 is adjusted, the vertical distance between the wafer to be processed W and the supporting wafer S is adjusted to be a predetermined distance (process A9 of FIG. 27). Meanwhile, the predetermined distance is a height where the central portion of the supporting wafer S comes in contact with the wafer to be processed W when the seal material 231 is in contact with the first holding unit 200 and in addition, the central portions of the second holding unit 201 and the supporting wafer S are flexed, as described below. In this manner, a closed bonding space R is formed between the first holding unit 200 and the second holding unit 201.

Then, the atmosphere of the bonding space R is sucked from the atmosphere intake tube 241. In addition, when the pressure within the bonding space R is decompressed to, for example, 0.3 atmosphere (=0.03 MPa), a pressure difference between the pressure applied to the top surface of the second holding unit 201 and the pressure within the bonding space R, i.e. 0.7 atmosphere (=0.07 MPa) is applied to the second holding unit 201. Then, as illustrated in FIG. 29, the central portion of the second holding unit 201 is flexed and hence, the central portion of the supporting wafer S held on the second holding unit 201 is also flexed. Meanwhile, even if the pressure within the bonding space R is decompressed to 0.3 atmosphere (=0.03 MPa) as described above, the supporting wafer S remains in the state where it is held on the second holding unit 201 because the pressure between the second holding unit 201 and the supporting wafer S is 0.1 atmosphere (=0.01 MPa).

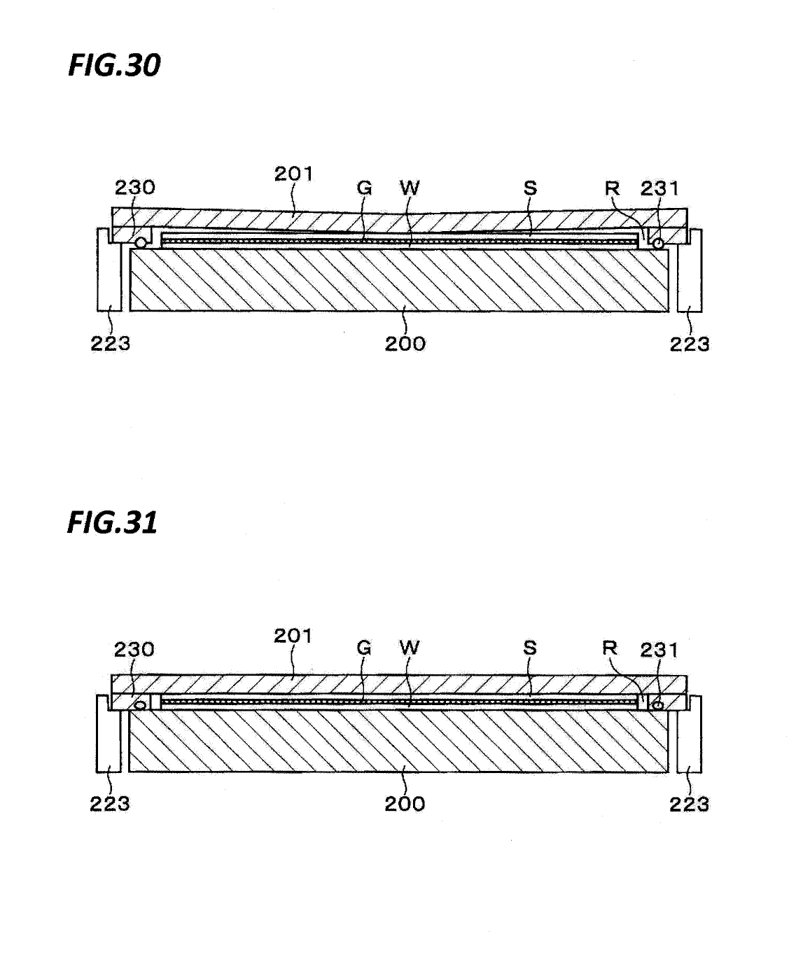

Thereafter, the atmosphere of the bonding space R is also sucked to decompress the inside of the bonding space R. Then, when the pressure within the bonding space R becomes 0.1 atmosphere (=0.01 MPa) or less, the second holding unit 201 may not hold the supporting wafer S. Thus, as illustrated in FIG. 30, the supporting wafer S drops downward so that the entire bonded surface Sᵢ of the supporting wafer S comes in contact with the entire bonded surface W_{I} of the wafer to be processed W. At this time, the supporting wafer S is sequentially contacted with the wafer to be processed W from the contacted central portion toward the outside in the radial direction. That is, for example, even if air, which may form voids, exists within the bonding space R, the air will always exist outside a portion where the supporting wafer S comes in contact with the wafer to be processed W. Thus, the air may be pushed out of the gap between the wafer to be processed W and the supporting wafer S. As a result, the wafer to be processed W and the supporting wafer S are bonded with each other by the adhesive G while suppressing the occurrence of voids (process A10 in FIG. 27).

Thereafter, as illustrated in FIG. 31, the height of the support member 223 is adjusted such that the bottom surface of the second holding unit 201 comes in contact with the non-bonded surface S_{N} of the supporting wafer S. At this time, the seal material 231 is elastically deformed and the first holding unit 200 and the second holding unit 201 come in close contact with each other. In addition, the second holding unit 201 is pressed downward with a predetermined pressure, for example, 0.5 MPa by the pressing mechanism 260 while the wafer to be processed W and the supporting wafer S are heated to a predetermined temperature, for example, 200° C. by the heating mechanism 211, 152. Then, the wafer to be processed W and the supporting wafer S are more strongly adhered and bonded with each other (process A11 in FIG. 27).

A superimposed wafer T obtained by bonding the wafer to be processed W and the supporting wafer S is conveyed from the bonding section 110 to delivery section 110 by the first conveyance arm 170 of the conveyance section 112. The superimposed wafer T conveyed to the delivery section 110 is delivered to the delivery arm 120 through the wafer support pins 121 and then delivered from the delivery arm 120 to the wafer conveyance device 61. Then, the superimposed wafer T is conveyed to the transition device 51 by the wafer conveyance device 61, and then, conveyed to the cassette C_{T} of the predetermined cassette mounting plate 11 by the wafer conveyance device 22 of the carry in/out station 2. In this manner, bonding processings of a series of wafers to be processed W and supporting wafers S are finished.

According to an exemplary embodiment described above, in the coating device 40 and the heat treatment device 41, a wafer to be processed W is sequentially processed such that the wafer to be processed W is coated with an adhesive G and heated to a predetermined temperature, and in the bonding device 30, the front and back surfaces of a supporting wafer S are inverted. Thereafter, in the bonding device 30, the wafer to be processed W which is coated with the adhesive G and heated to the predetermined temperature and the supporting wafer S of which the front and back surfaces are inverted are bonded with each other. Thus, according to the present exemplary embodiment, the wafer to be processed W and the supporting wafer S may be processed in parallel. Further, while the wafer to be processed W and the supporting wafer S are bonded with each other in the bonding device 30, other wafers to be processed W and supporting wafers S may be processed in the coating device 40, heat treatment device 41, and the bonding device 30. Accordingly, the bonding between the wafers to be processed W and the supporting wafers S may be efficiently performed and thus, the throughput of a bonding processing may be improved.

Here, when the bonding device of Patent Document 1 as described above is used, it is required to invert the front and back surfaces of a wafer in the outside of the bonding device. In such a case, because it is required to convey the wafer to the bonding device after the front and back surfaces are inverted, there is a room for improvement in the entire bonding processing throughput. In addition, when the front and back surfaces of the wafer are inverted, the bonded surface of the wafer faces downward. In such a case, when a conveyance device configured to hold the back surface of a conventional wafer is used, the bonded surface of the wafer is held on the conveyance device. Therefore, when, for example, particles are adhered to the conveyance device, the particles may be adhered to the bonded surface of the wafer. In addition, because the bonding device of the Patent Document 1 does not have a function of adjusting the directions of the wafer and the supporting substrate in the horizontal direction, the wafer and the supporting substrate may be bonded to be misaligned.

In view of this, according to an exemplary embodiment, both the inverting section 111 and the bonding section 113 are provided within the bonding device 30. Thus, the supporting wafer S may be conveyed to the bonding section 113 by the conveyance section 112 directly after inverting the supporting wafer S. In this manner, because the inverting of the supporting wafer S and the bonding of the wafer to be processed W and the supporting wafer S are performed at the same time within the single bonding device 30, the bonding of the wafer to be processed W and the supporting wafer S may be efficiently performed. Accordingly, the bonding processing throughput may be further improved.

In addition, because the second conveyance arm 171 of the conveyance section 112 holds the outer peripheral portion of the bonded surface S_{J} of the supporting wafer S, the bonded surface S_{J} is not polluted by, for example, particles adhered to the second conveyance arm 171. Further, the first conveyance arm 170 of the conveyance section 112 holds the non-bonded surface W_{N} of the wafer to be processed W, the bonded surface S_{J} of the supporting wafer S, and the back surface of the superimposed wafer T to convey the wafer to be processed W, the supporting wafer S, and the superimposed wafer T. As described above, because the conveyance section 112 is provided with two kinds of conveyance arms 170, 171, the wafer to be processed W, the supporting wafer S, and the superimposed wafer T may be efficiently conveyed.

Further, in the second conveyance arm 171, the tapered portion 194 of each of the second holding members 192 has an inner surface which is enlarged in a taper shape from the bottom side toward the top side. Accordingly, for example, even if the supporting wafer S delivered to the second holding members 192 is misaligned from a predetermined position in the horizontal direction, the supporting wafer S may be smoothly guided to be positioned by the tapered portion 194.

In addition, in the first conveyance arm 170, because the guide members 183, 184 are installed on the arm unit 180, the wafer to be processed W, the supporting wafer S, or the superimposed wafer T may be prevented from slipping out or sliding sown from the first conveyance arm 170.

In addition, the inverting section 720 may invert the front and back surfaces of the supporting wafer S by the first drive unit 153 and adjust the direction of the supporting wafer S and the wafer to be processed W in the horizontal direction by the position adjusting mechanism 160. Accordingly, in the bonding section 113, the supporting wafer S and the wafer to be processed W may be properly bonded with each other. In addition, the bonding of the wafer to be processed W and the supporting wafer S may be efficiently performed in the bonding section 113 because the inverting of the supporting wafer S and the adjusting of the direction of the supporting wafer S and the wafer to be processed W in the horizontal direction may be performed in unison in the single inverting section 111. Accordingly, the bonding processing throughput may be further improved.

In addition, because the delivery sections 110 are arranged in two tiers in the vertical direction, at least two of a wafer to be processed W, a supporting wafer S, and a superimposed wafer T may be delivered simultaneously. Accordingly, because the wafer to be processed W, the supporting wafer S, and the superimposed wafer T may be efficiently delivered between the bonding device 30 and the outside, the bonding processing throughput may be further improved.

In addition, because the inside of the heat treatment device 41 may be maintained as an inert gas atmosphere, it is possible to suppress an oxide film from being formed on the wafer to be processed W. Therefore, heat treatment of the wafer to be processed W may be properly performed.

In addition, the pressure within the heat treatment device 41 is set to a negative pressure in relation to the pressure within the wafer conveyance region 60. Therefore, when the opening/closing shutter of the processing container of the heat treatment device 41 is opened, air flow directed from the wafer conveyance region 60 to the heat treatment device 41 is generated. Accordingly, because the atmosphere heated within the heat treatment device 41 is not flown into the wafer conveyance region 60, the wafer to be processed W, the supporting wafer S, and the superimposed wafer T may be properly conveyed at a predetermined temperature while they are being conveyed within the wafer conveyance region 60.

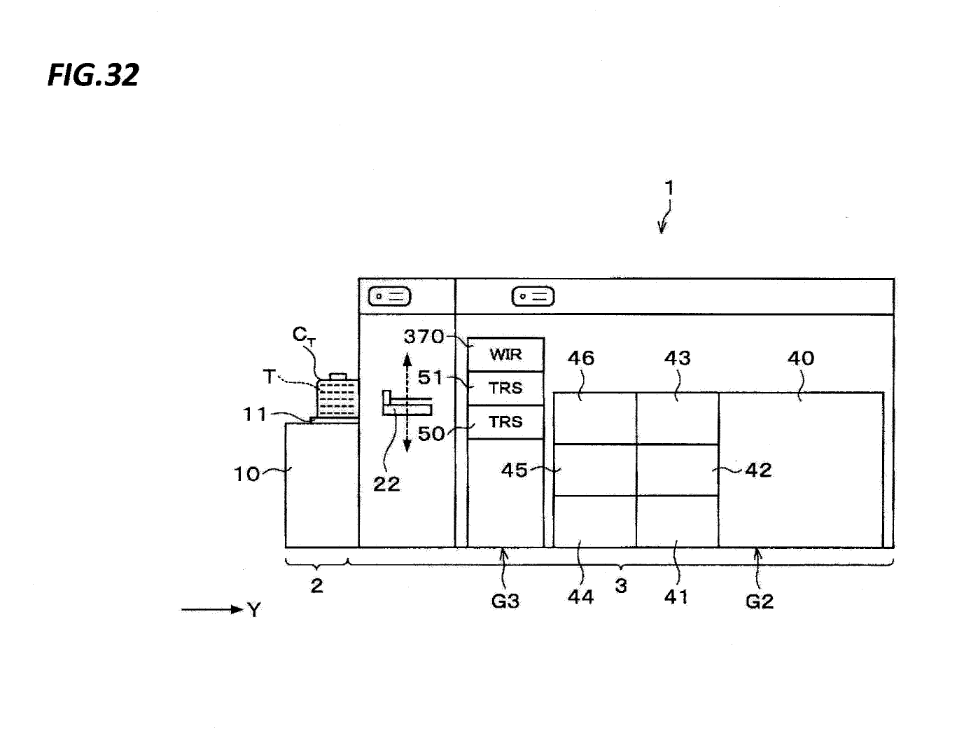

The bonding system 1 according to an above-described exemplary embodiment may be further provided with an inspection device 370 configured to inspect a superimposed wafer T bonded by the bonding device 30, as illustrated in FIG. 32. The inspection device 370 is arranged, for example, at the uppermost layer of the third processing block G3.

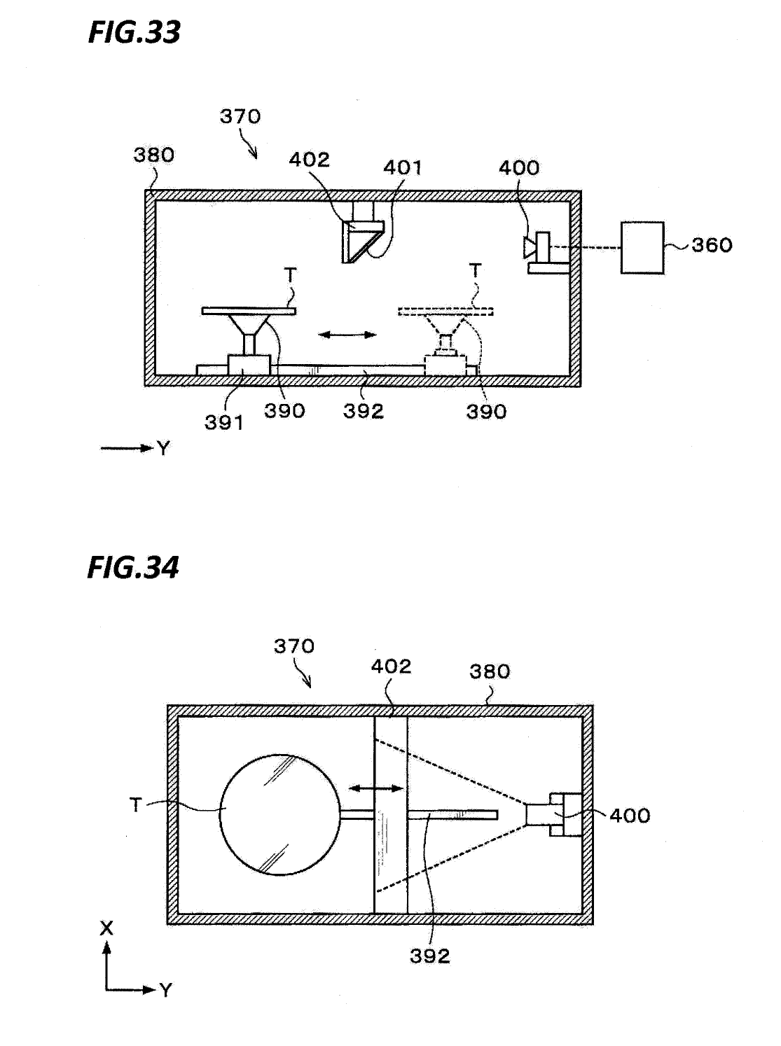

The inspection device 370 includes a processing container 380, as illustrated in FIG. 33. The side wall of the wafer conveyance region 60 side of the processing container 380 is formed with a carry in/out port (not illustrated) configured to carry in/out the superimposed wafer T and an opening/closing shutter (not illustrated) is installed in the carry in/out port.

As illustrated in FIG. 33, a chuck 390 configured to suck and maintain the superimposed wafer T is provided within the processing container 380. The chuck 390 may be rotated or stopped by a chuck drive unit 391 which is provided with, for example, a motor, and has an alignment function that adjusts the position of the superimposed wafer T. On the bottom of the processing container 380, a rail 392 is installed to extend from one end side (at the negative side in the Y direction in FIG. 33) to the other end side (at the positive side in the Y direction in FIG. 33) within the processing container 380. The chuck drive unit 391 is attached on the rail 392. The chuck 390 may be moved along the rail 392 by the chuck drive unit 391 and freely moved up and down.

An image capturing unit 400 is installed on the side wall of the other end side (at the positive side in the Y direction in FIG. 33) within the processing container 380. As for the image capturing unit 400, for example, a wide angle CCD (charge-coupled device) camera is used. A half mirror 401 is installed in the vicinity of an upper center of the processing container 380. The half mirror 401 is installed at a position opposite to the image capturing unit 400 to be inclined by 45 degrees from the vertical direction. An infrared irradiation unit 402 configured to irradiate infrared rays to the superimposed wafer T is provided above the half mirror 401, and the half mirror 401 and the infrared ray irradiation unit 402 are fixed to the top of the processing container 380. In addition, the infrared ray irradiation unit 402 extends in the X direction as illustrated in FIG. 34.

In such a case, the superimposed wafer T bonded in process A11 in the above-described bonding device 30 is conveyed to the inspection device 370 by the wafer conveyance device 61. The superimposed wafer T conveyed into the inspection device 370 is delivered from the wafer conveyance device 61 to the chuck 390. Thereafter, the chuck 390 is moved along the rail 392 by the chuck drive unit 391 and infrared rays are irradiated to the superimposed wafer T from the infrared irradiation unit 402 while the superimposed wafer T is moved. In addition, the entire surface of the superimposed wafer T is image-captured by the image-capturing unit 400 through the half mirror 401. The captured image of the superimposed wafer T is output to the control unit 360 and the control unit 360 inspects whether the bonding of the superimposed wafer T is properly performed, for example, presence or absence of voids in the superimposed wafer T. Thereafter, the superimposed wafer T is conveyed to the transition device 51 by the wafer conveyance device 61 and then, conveyed to a cassette C_{T} on a predetermined cassette mounting plate 11 by the wafer conveyance device 22 of the carry in/out station 2.

According to an above-described exemplary embodiment, the superimposed wafer T may be inspected by the inspection device 370. Thus, a processing condition in the bonding system 1 may be corrected based on the inspection results. Accordingly, the wafer to be processed W and the supporting wafer S may be bonded further properly.

In addition, in the bonding system 1 of the above-described exemplary embodiment, a temperature control device (not illustrated) may be provided to cool the wafer to be processed W heat-treated in the heat treatment device 41 to a predetermined temperature. In such a case, the temperature of the wafer to be processed W may be adjusted to a suitable temperature so that a subsequent processing may be more smoothly performed.

Meanwhile, in an above-described exemplary embodiment, a wafer to be processed W and a supporting wafer S are bonded in the state where the wafer to be processed W and the supporting wafer S are arranged below and above. However, the vertical arrangement of the wafer to be processed W and the supporting wafer S may be inverted. In this case, processes A1 to A4 as described above are performed on the supporting wafer S, and the adhesive G is coated on the bonded surface S_{J} of the supporting wafer S. In addition, processes A5 to A7 are performed on the wafer to be processed W so that the front and back surfaces of the wafer to be processed W are inverted. Then, processes A8 to A11 are performed to bond the supporting wafer S and the wafer to be processed W.

In addition, in an above-described exemplary embodiment, any one of a wafer to be processed W and a supporting wafer S is coated with the adhesive G by the coating device 40. However, the adhesive G may be coated on both the wafer to be processed W and the supporting wafer S.

In addition, in an above-described exemplary embodiment, the first holding unit 200 is moved in the vertical direction and horizontal direction from the bonding device 30. However, the second holding unit 201 may be moved in the vertical direction and horizontal direction. Alternatively, both the first holding unit 200 and the second holding unit 201 may be moved in the vertical direction and the horizontal direction.

In an above-described exemplary embodiment, in the bonding device 30, the first conveyance arm 170 of the conveyance section 112 includes the O-rings 182 in order to hold a wafer to be processed W, a supporting wafer S, or a superimposed wafer T. However, the present invention is not limited thereto. For example, as to the first holding member, it is sufficient if frictional force is produced between the first holding member and the rear faces of the wafer to be processed W, the supporting wafer S, and the superimposed wafer T and other sucking pads or the like may be provided instead of the O-rings 182.

Meanwhile, in an above-described exemplary embodiment, the conveyance section 112 may be omitted from the bonding device 30. In such a case, a wafer to be processed W and a supporting wafer S are delivered between the delivery section 110 and the inverting section 111 and the wafer to be processed W and the supporting wafer S are delivered between the inverting section 111 and the bonding section 113 by moving the holding arm 150 of the inverting section 111. In the bonding device 30 from which the conveyance section 112 is omitted, the conveyance of the wafer to be processed W and the supporting wafer S is performed in addition to the inverting of the wafer to be processed W and the supporting wafer S and the adjustment of direction in the horizontal direction in the inverting section 111. Therefore, the bonding processing throughput is deteriorated as compared with the above-described exemplary embodiments. For example, however, in a case where high throughput in bonding processing of a wafer to be processed W and a supporting wafer S is not requested, it is useful to use the bonding device 30 from which the conveyance section 112 is omitted since the configuration of the device may be simplified.

In addition, in an above-described exemplary embodiment, the coating device 40 includes one adhesive nozzle 293 but may include, for example, two adhesive nozzles. In such a case, it is possible to cope with a case in which two kinds of adhesives are used as well as to use one adhesive for the purpose of bonding evaluation.

Here, for a superimposed wafer T bonded in the bonding system 1, a predetermined processing, for example, a polishing processing, is performed on the non-bonded surface W_{N} of the wafer to be processed W in the outside of the bonding system 1. Thereafter, the superimposed wafer T is separated into the wafer to be processed W and the supporting wafer S so that the wafer to be processed W is made into a product.

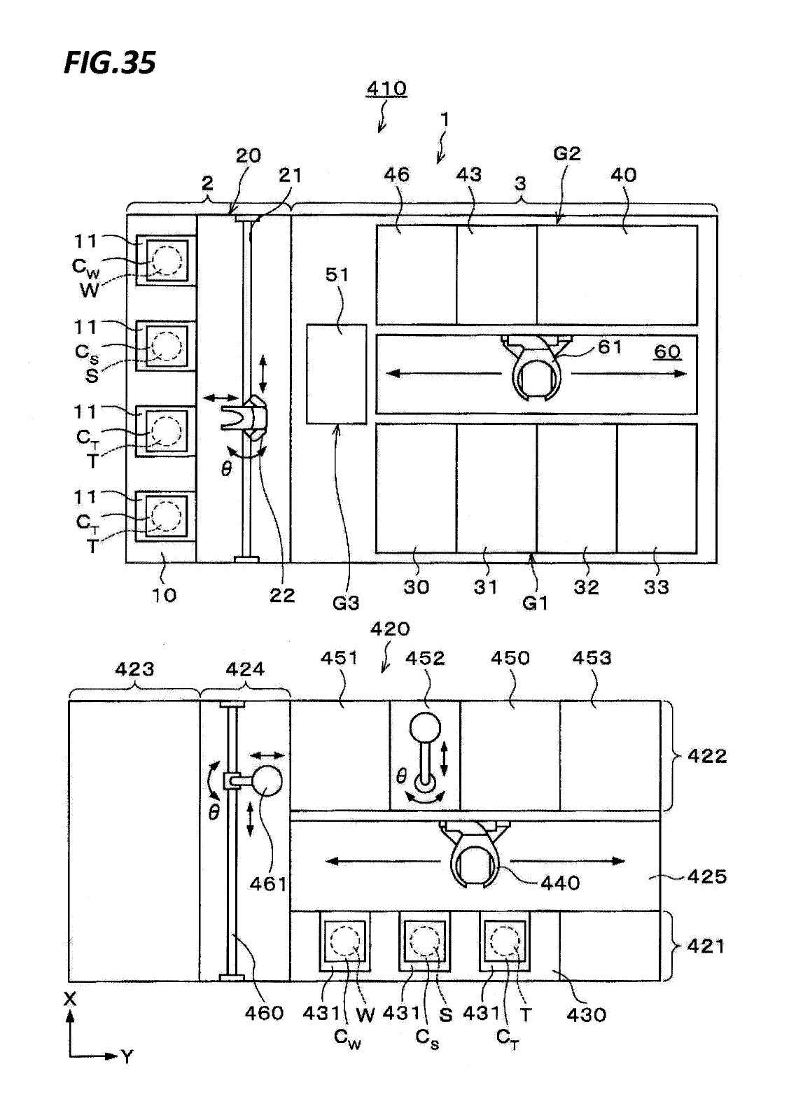

In an exemplary embodiment, a substrate processing system 410 provided with the bonding system 1 as illustrated in FIG. 35 may further include a separating system 420 configured to separate a superimposed wafer T into a wafer to be processed W and a supporting wafer S.

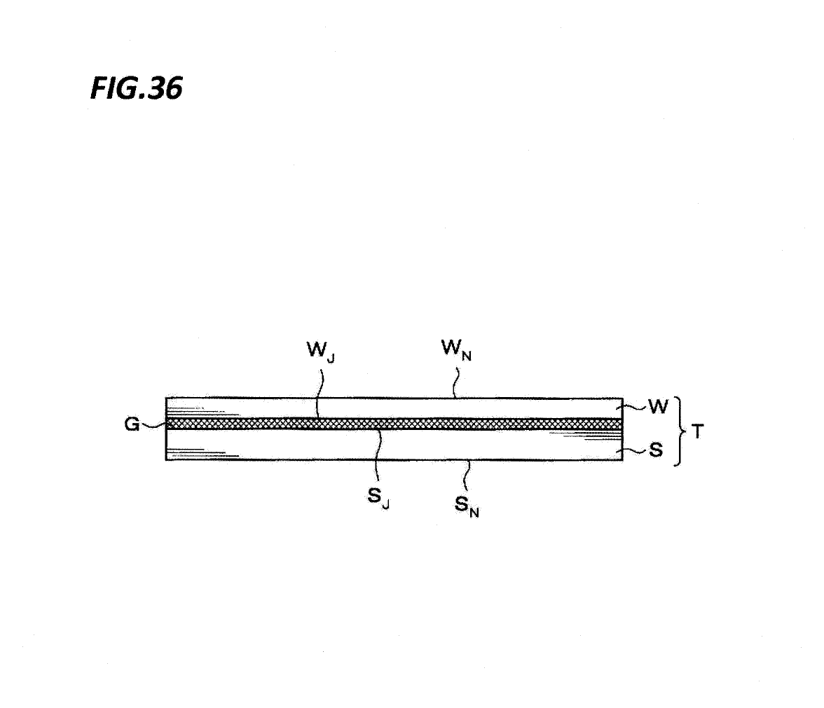

In the separating system 420, a superimposed wafer T bonded by an adhesive G as illustrated in FIG. 36 is separated into a wafer to be processed W and a supporting wafer S. In such a case, the bonded surface W_{J} of the wafer to be processed W is formed with a plurality of electronic circuits as described above. Further, the non-bonded surface W_{N} of the wafer to be processed W is polished so that the wafer to be processed W has a reduced thickness (e.g., a thickness of 50 μm).

As illustrated in FIG. 35, the separating system 420 includes: a carry in/out station 421 configured such that cassettes C_{W}, C_{S}, C_{T}, each of which may accommodate a plurality of wafers to be processed W, a plurality of supporting wafers S, and a plurality of superimposed wafers T, are carried into/out of the carry in/out station 421 from/to, for example, the outside of the carry in/out station 421; a separating processing station 422 including various processing devices to perform a predetermined processing on the wafers to be processed W, the supporting wafers S, and the superimposed wafers T; and an interface station 424 configured to deliver the wafer to be processed W to or out of a post-processing station 423 adjacent to the separating processing station 422. The carry in/out station 421, the separating processing station 422, and the interface station 424 are integrally connected with each other.

The carry in/out station 421 and the separating processing station 422 are arranged in parallel to each other in the X direction (the vertical direction in FIG. 35). A wafer conveyance region 425 is formed between the carry in/out station 421 and the separating processing station 422. In addition, the interface station 424 is arranged at the negative side in the Y direction (at the left side in FIG. 35) of the carry in/out station 421, the separating processing station 422, and the wafer conveyance region 425.

The carry in/out station 421 is provided with a cassette mounting stage 430. The cassette mounting stage 430 is provided with a plurality of (e.g., three) cassette mounting plates 431. The cassette mounting plates 431 are arranged in a row in the Y direction (the horizontal direction in FIG. 35). The cassettes C_{W}, C_{S}, C_{T} may be respectively placed on the cassette mounting plates 431 when the cassettes C_{W}, C_{S}, C_{T} are carried into or out of the separating system 420. As described above, the carry in/out station 421 is configured to be capable of holding a plurality of wafers to be processed W, a plurality of supporting wafers S, and a plurality of superimposed wafers T. Meanwhile, the number of the cassette mounting plates 431 may be optionally determined without being limited to the present exemplary embodiment. Further, the plurality of superimposed wafer T carried into the carry in/out station 421 are inspected in advance and classified into the superimposed wafers T each of which includes a normal wafer to be processed W and the superimposed wafers T each of which includes a defective wafer to be processed W.

In the wafer conveyance region 425, a first conveyance device 440 is arranged. The first conveyance device 440 includes a conveyance arm which may be moved, for example, in the vertical and horizontal directions (the Y- and X directions) and around the vertical axis. The first conveyance device 440 may be moved within the wafer conveyance region 425 so as to convey a wafer to be processed W, a supporting wafer S, and a superimposed wafer T between the carry in/out station 421 and the separating processing station 422.

The separating processing station 422 includes a separating device 450 configured to separate a superimposed wafer T into a wafer to be processed W and a supporting wafer S. At the negative side in the Y direction of the separating device 450 (at the left side in FIG. 35), a first cleaning device 451 configured to clean a separated wafer to be processed W is arranged. Between the separating device 450 and the first cleaning device 451, a second conveyance device 452 is provided as another conveyance device. Further, at the positive side in the Y direction of the separating device 450 (at the right side in FIG. 35), a second cleaning device 453 configured to clean a separated supporting wafer S is arranged. As described above, the separating processing station 422 is provided with the first cleaning device 451, the second conveyance device 452, the separating device 450, and the second cleaning device 453 which are arranged in this order from the interface station 424 side in parallel to each other.

In the interface station 424, a third conveyance device 461 is provided as another conveyance device which is movable on a conveyance path 460 extending in the X direction. The third conveyance device 461 is also movable in the vertical direction and around the vertical axis (in the 0 direction), and may convey a wafer to be processed W between the separating processing station 422 and the post-processing station 423.

Meanwhile, in the post-processing station 423, predetermined post-processings are performed on a wafer to be processed W which has been separated in the separating processing station 422. As the predetermined post-processings, for example, a processing of mounting the wafer to be processed W, a processing of inspecting an electric characteristic of the electronic circuits on the wafer to be processed W, and a processing of dicing the wafer to be processed W for each chip are performed.

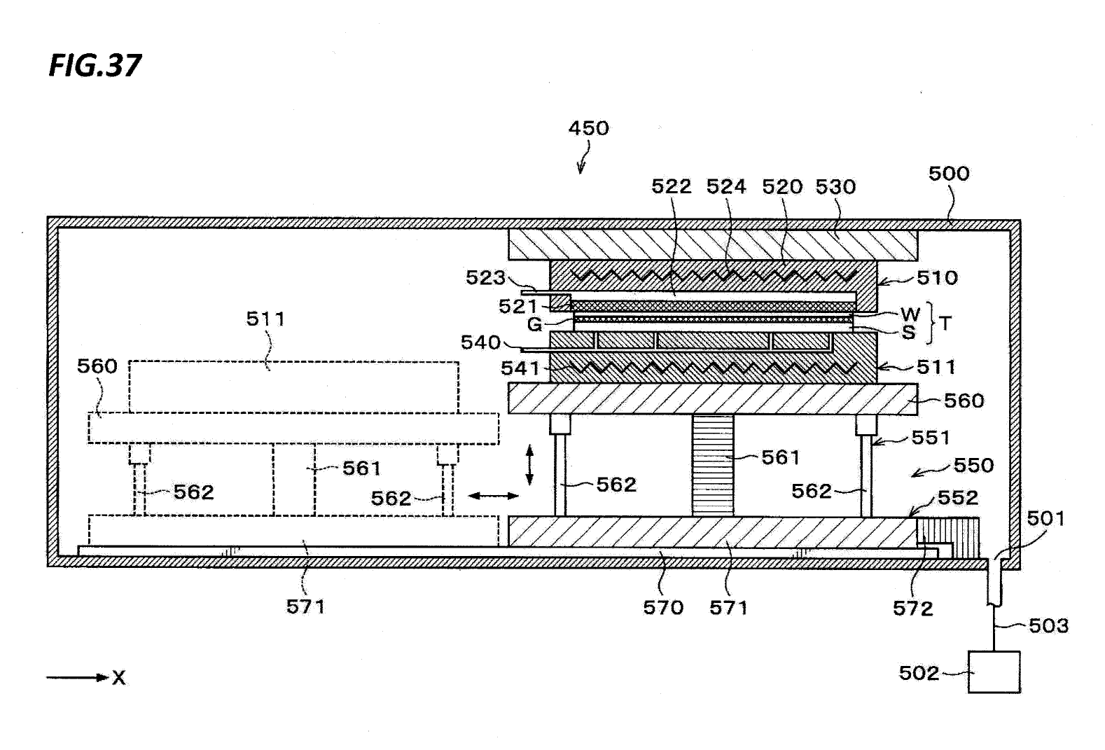

Next, descriptions will be made on a configuration of the separating device 450. As illustrated in FIG. 37, the separating device 450 includes a processing container 500 that may seal the interior thereof. A side wall of the processing container 500 is formed with a carry in/out port (not illustrated) for a wafer to be processed W, a supporting wafer S, and a superimposed wafer T, and an opening/closing shutter (not illustrated) is installed in the carry in/out port.

In the bottom of the processing container 500, an intake port 501 through which the atmosphere within the processing container 500 may be sucked if formed. An intake tube 503 is connected to the intake port 501 in which the intake tube 503 is communicated with a negative pressure generating device 502 such as, for example, a vacuum pump.

Within the processing container 500, a first holding unit 510 configured to suck and hold a wafer to be processed W at the bottom side and a second holding unit 511 configured to hold a supporting wafer S placed on the top thereof are provided. The first holding unit 510 is provided above the second holding unit 511 and arranged to be opposite to the second holding unit 511. That is, within the processing container 500, the separating processing is performed on the superimposed wafer T in the state where the wafer to be processed W and the supporting wafer S are arranged up and down.

In the first holding unit 510, for example, a porous chuck is used. The first holding unit 510 includes a flat body 520. A porous member 521 is provided on the bottom of the body 520. The porous member 521 has a diameter which is substantially the same as, for example, that of a wafer to be processed W and is in contact with the non-bonded surface W_{N} of the wafer to be processed W. Meanwhile, for example, a silicon carbide is used as for the porous member 521.

In addition, a suction space 522 is formed within the body 520 and above the porous member 521. The suction space 522 is formed to cover, for example, the porous member 521. A suction tube 523 is connected to the suction space 522. The suction tube 523 is connected to a negative pressure generating device (not illustrated) such as, for example, a vacuum pump. Further, the non-bonded surface W_{N} of the wafer to be processed W is sucked through the suction space 522 and the porous member 521 from the suction tube 523, and the wafer to be processed W is sucked and held by the holding unit 510.

In addition, a heating mechanism 524 configured to heat the wafer to be processed W is provided within the body 520 and above the suction space 522. As for the heating mechanism 524, for example, a heater is used.

A support plate 530 is provided on the top of the first holding unit 510 so as to support the first holding unit 510. The support plate 530 is supported on the ceiling of the processing container 500. Meanwhile, the support plate 530 of the present exemplary embodiment may be omitted and the first holding unit 510 may be supported while being contacted with the ceiling of the processing container 500.

A suction tube 540 configured to suck and hold a supporting wafer S may be provided within the second holding unit 511. The suction tube 540 is connected to a negative pressure generating device (not illustrated) such as, for example, a vacuum pump.

In addition, a heating mechanism 541 configured to heat the supporting wafer S is provided within the second holding unit 511. As for the heating mechanism 541, for example, a heater is used.

A moving mechanism 550 configured to move the second holding unit 511 and the supporting wafer S in the vertical direction and the horizontal direction is provided under the second holding unit 511. The moving mechanism 550 includes a vertical moving unit 551 configured to move the second holding unit 511 in the vertical direction and a horizontal moving unit 552 configured to move the second holding unit 511 in the horizontal direction.

The vertical moving unit 551 includes a support plate 560 configured to support the bottom surface of the second holding unit 511, a drive unit 561 configured to lift the support plate 560, and a support member 562 configured to support the support plate 560. The drive unit 561 includes, for example, a ball screw (not illustrated) and a motor (not illustrated) that rotates the ball screw. In addition, the support member 562 is configured to be extendible and retractable in the vertical direction, and such a support member is installed at, for example, three locations between the support plate 560 and a support 571 to be described later.

The horizontal moving unit 552 includes a rail 570 extending along the X direction (the horizontal direction in FIG. 37), the support 571 attached to the rail 570, and a drive unit 572 configured to move the support 571 along the rail 570. The drive unit 572 includes, for example, a ball screw (not illustrated) and a motor (not illustrated) that rotates the ball screw.

Meanwhile, a lift pin (not illustrated) configured to support and lift a superimposed wafer T or a supporting wafer S at the bottom side thereof is provided below the second holding unit 511. The lift pin is inserted through a through hole (not illustrated) formed in the second holding unit 511 to be capable of protruding from the top surface of the second holding unit 511.

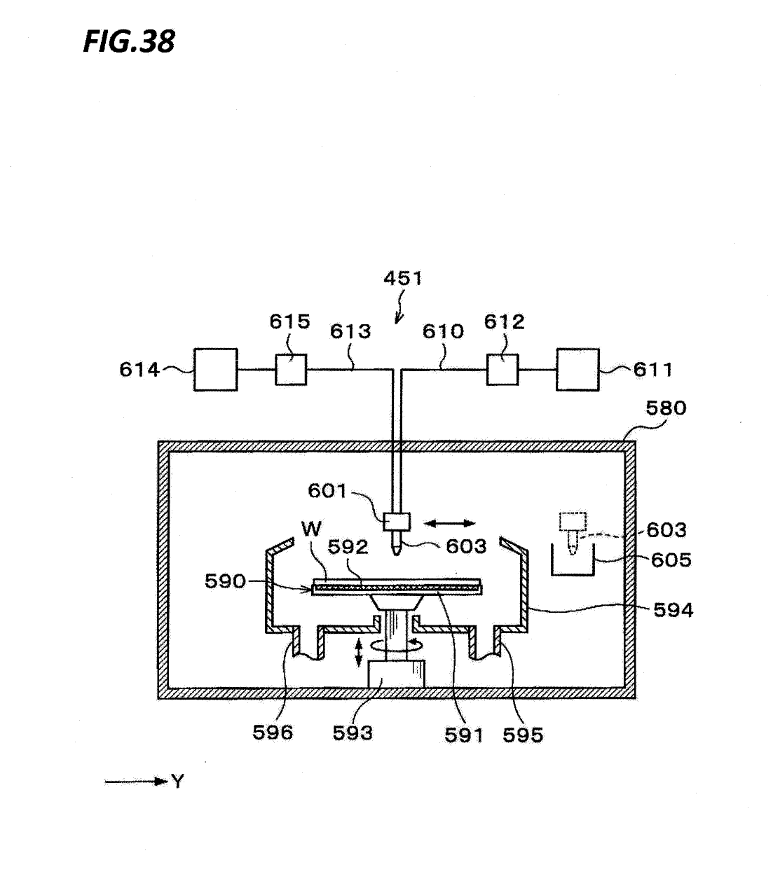

Next, descriptions will be made on a configuration of the above-described first cleaning device 451. The first cleaning device 451 is provided with a processing container 580 of which the inside may be sealed as illustrated in FIG. 38. In a side wall of the processing container 580, a carry in/out port (not illustrated) for a wafer to be processed W and an opening/closing shutter (not illustrated) is installed in the carry in/out port.

At the central portion of the processing container 580, a porous chuck 590 is provided to hold and rotate the wafer to be processed W. The porous chuck 590 includes a flat body 591, and a porous member 592 provided on the top of the body 591. The porous member 592 has a diameter which is substantially the same as, for example, that of the wafer to be processed W and comes in contact with the non-bonded surface W_{N} of the wafer to be processed W. Meanwhile, as for the porous member 592, for example, a silicon carbide is used. A suction tube (not illustrated) is connected to the porous member 592 and the wafer to be processed W may be sucked and held on the porous chuck 590 by sucking the non-bonded surface W_{N} of the wafer to be processed W through the porous member 592 from the suction tube.

A chuck drive unit 593 provided with, for example, a motor, is provided below the porous chuck 590. The porous chuck 590 may be rotated at a predetermined speed by the chuck drive unit 593. Further, the chuck drive unit 593 is provided with a lift drive source such as, for example, a cylinder, so that the porous chuck 590 may be lifted.

A cup 594 is installed around the porous chuck 590 to receive and recover a liquid scattered or dropped from the wafer to be processed W. A discharge tube 595 configured to discharge the recovered liquid and an exhaust tube 596 configured to evacuated the atmosphere within the cup 594 to a vacuum state are connected to the bottom of the cup 594.

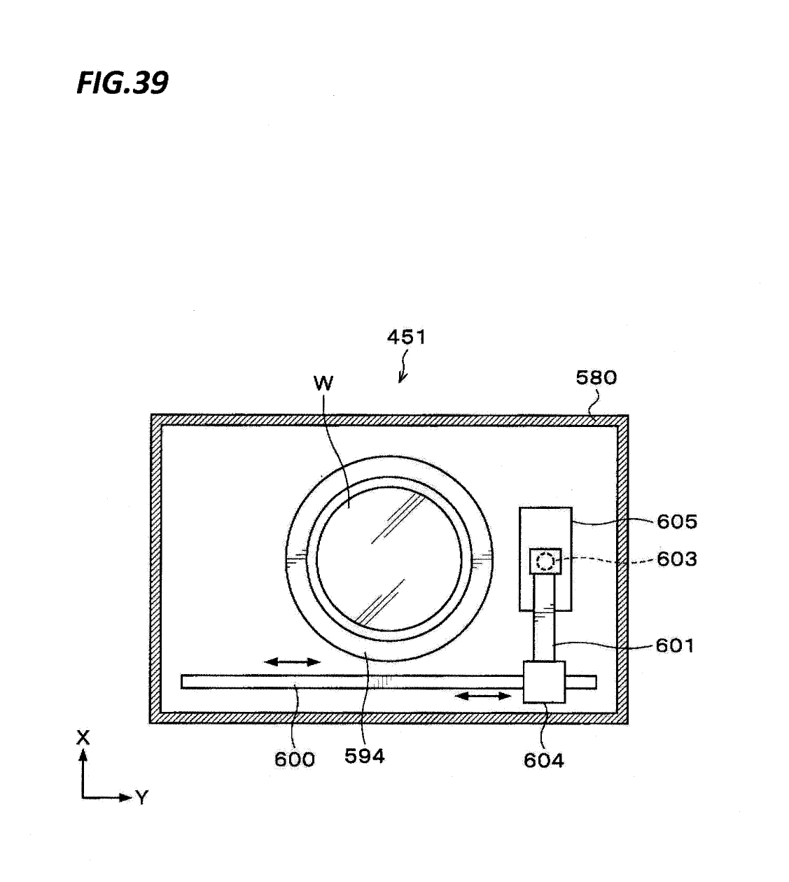

As illustrated in FIG. 39, a rail 600 extending along the Y direction (in the horizontal direction in FIG. 39) is formed at a side of the cup 594 at the negative direction side in the X direction (at the lower side in FIG. 39). The rail 600 is formed to extend, for example, from the outside of the cup 594 at the negative side in the Y direction (at the left side in FIG. 39) to the outside at the positive side in the Y direction (at the right side in FIG. 39). An arm 601 is attached to the rail 600.

As illustrated in FIGS. 38 and 39, the arm 601 supports a cleaning liquid nozzle 603 configured to supply a cleaning liquid, for example, an organic solvent, to the wafer to be processed W. The arm 601 may be moved on the rail 600 by a nozzle drive unit 604 illustrated in FIG. 39. As a result, the cleaning liquid nozzle 603 may be moved from a standby section 605 provided at the outside of the cup 594 at the positive side in the Y direction to a position above the central portion of the wafer to be processed W within the cup 594, and may also be moved above the wafer to be processed W in the radial direction of the wafer to be processed W. In addition, because the arm 601 may be lifted by the nozzle drive unit 604 so that the height of the cleaning liquid nozzle 603 may be adjusted.

As for the leaning liquid nozzle 603, for example, a two-fluid nozzle is used. As illustrated in FIG. 38, a supply tube 610 is connected to the cleaning liquid nozzle 603 to supply a cleaning liquid to the cleaning liquid nozzle 603. The supply tube 610 is communicated with a cleaning liquid supply source 611 which stores the cleaning liquid therein. The supply tube 610 is formed with a supply device group 612 that includes, for example, a valve or a flow control unit that controls the flow of the cleaning liquid. In addition, the cleaning liquid nozzle 603 is connected with a supply tube 613 configured to supply an inert gas such as, for example, nitrogen gas to the cleaning liquid nozzle 603. The supply tube 613 is communicated with a gas supply source 614 that stores an inert gas therein. The supply tube 613 is formed with a supply device group 615 such as, for example, a valve or a flow control unit that controls the flow of the inert gas. In addition, the cleaning liquid and the inert gas are mixed within the cleaning liquid nozzle 603 to be supplied from the cleaning liquid nozzle 603 to the wafer to be processed W. Hereinafter, the mixture of the cleaning liquid and the inert gas may be merely referred to as a “cleaning liquid”.

Meanwhile, under the porous chuck 590, a lift pin (not illustrated) may be provided so as to support and lift the wafer to be processed W at the bottom side. In such a case, the lift pin is inserted through a through hole (not illustrated) formed in the porous chuck 590 to be capable of protruding from the top surface of the porous chuck 590. In addition, instead of lifting the porous chuck 590, the lift pin is lifted so as to deliver the wafer to be processed W to and from porous chuck 590.

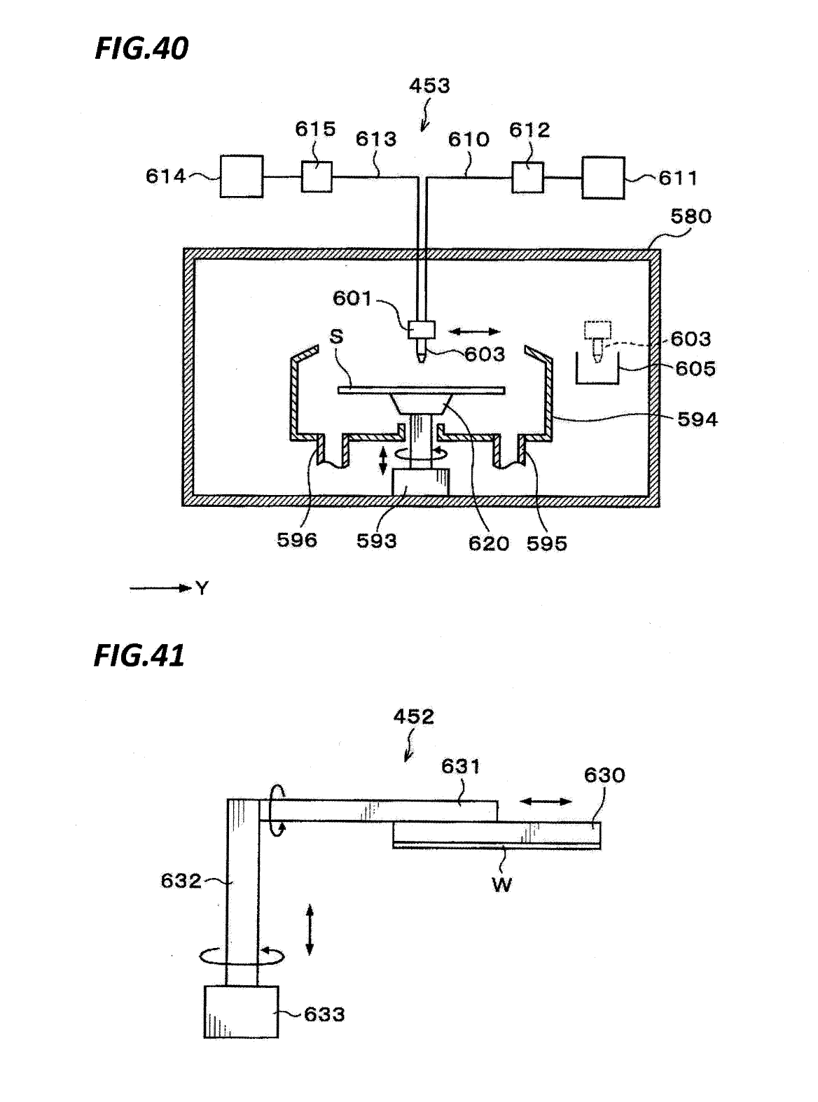

In addition, the configuration of the second cleaning device 453 is substantially the same as that of the first cleaning device 451 as described above. As illustrated in FIG. 40, the second cleaning device 453 is provided with a spin chuck 620, instead of the porous chuck 590 of the first cleaning device 451. The spin chuck 620 has a horizontal top surface where a suction port (not illustrated) is formed so as to suck, for example, a supporting wafer S. By the suction from the suction port, the supporting wafer S may be sucked and held on the spin chuck 620. Because the other configuration of the second cleaning device 453 is the same as that of the second cleaning device 453, the description thereof will be omitted.

In the second cleaning device 453, a backside rinse nozzle (not illustrated) may be provide under the spin chuck 620 so as to inject a cleaning liquid to the back surface of the supporting wafer S, i.e. the non-bonded surface S_{N}. The non-bonded surface S_{N} and the outer peripheral portion of the supporting wafer S are cleaned by the cleaning liquid injected from the backside rinse nozzle.

Next, descriptions on a configuration of the above-described second conveyance device 452 will be made. As illustrated in FIG. 41, the second conveyance device 452 includes a Bernoulli chuck 630 configured to hold a wafer to be processed W. The Bernoulli chuck 630 makes the wafer to be processed W float by ejecting air, and sucks and suspends the wafer to be processed W to hold the wafer to be processed W in a non-contact state. The Bernoulli chuck 630 is supported on a support arm 631. The support arm 631 is supported by a first drive unit 632. The support arm 631 may be rotated around the horizontal axis thereof by the first drive unit 632 and may be extended and retracted in the horizontal direction. A second drive unit 633 is provided below the first drive unit 632. The first drive unit 632 may be rotated around the vertical axis thereof and lifted in the vertical direction by the second drive unit 633.

Because the third conveyance device 461 has the same configuration as the above-described second conveyance device 452, the description thereof will be omitted. However, the second drive unit 633 of the third conveyance device 461 is attached to the conveyance path 460 illustrated in FIG. 35 so that the third conveyance device 461 may be moved on the conveyance path 460.

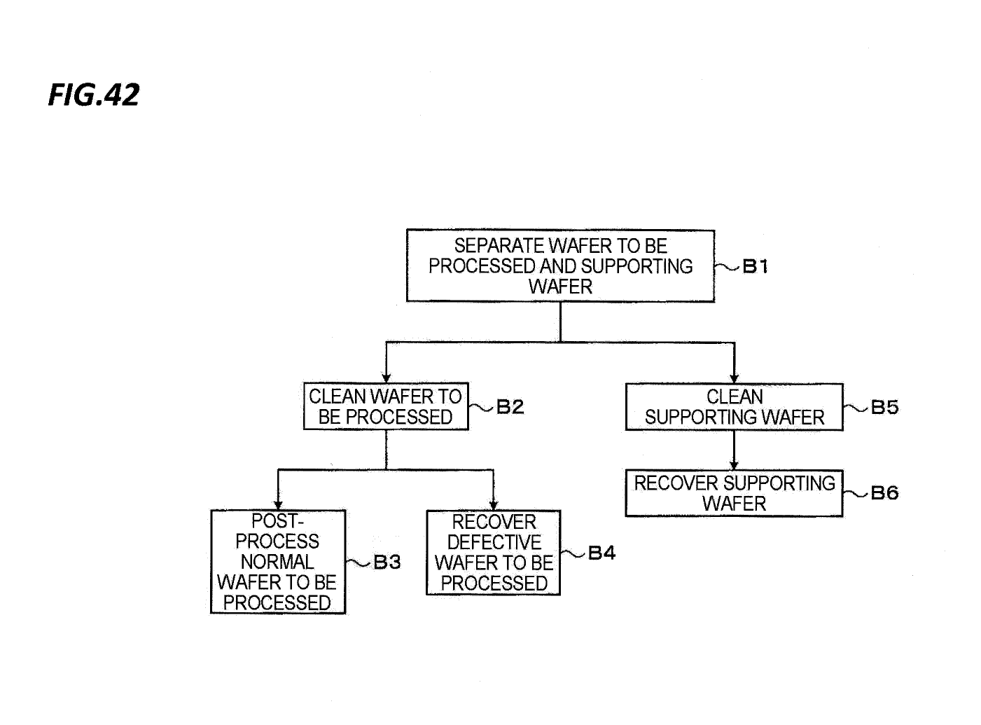

Next, descriptions will be made on a method of performing a separating process of a wafer to be processed W and a supporting wafer S using the separating system 420 configured as described above. FIG. 42 is a flowchart illustrating an example of principal processes of such a separating processing.

First, a cassette C_{T} that accommodates a plurality of superimposed wafers T, an empty cassette C_{W}, and another empty cassette C_{S} are placed on predetermined cassette mounting plates 431 of the carry in/out station 421, respectively. A superimposed wafer T in the cassette C_{T} is taken out by the first conveyance device 440 and conveyed to the separating device 450 of the separating processing station 422. At this time, the superimposed wafer T is conveyed in a state where the wafer to be processed W and the supporting wafer S are arranged up and down.

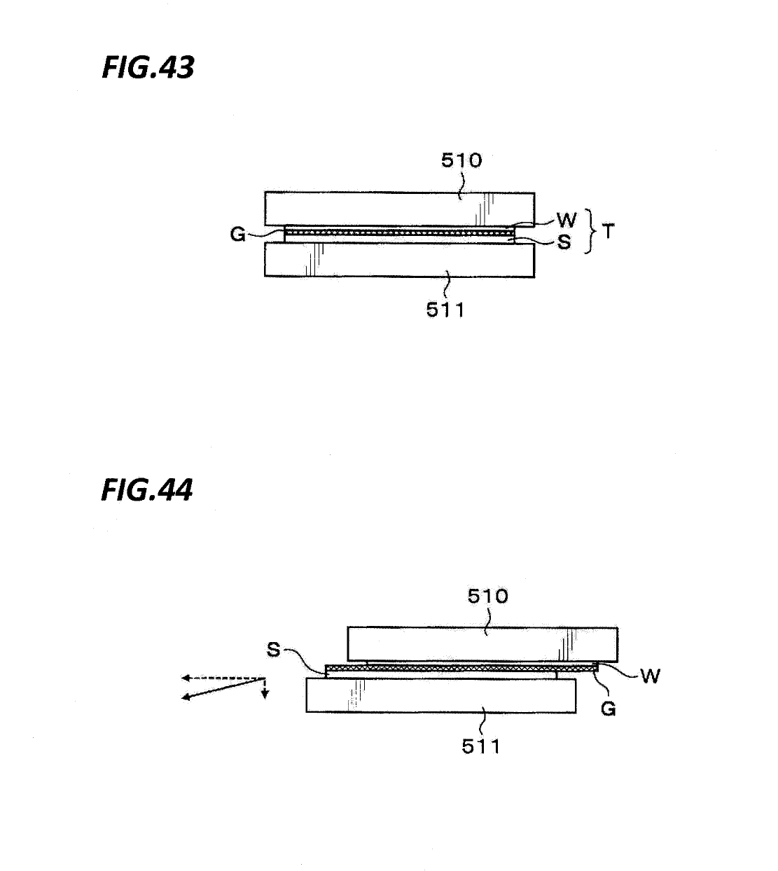

The superimposed wafer T carried into the separating device 450 is sucked and held by the second holding unit 511. Then, the second holding unit 511 is moved up by the moving mechanism 550 and the superimposed wafer T is introduced and held between the first holding unit 510 and the second holding unit 511, as illustrated in FIG. 43. At this time, the non-bonded surface W_{N} of the wafer to be processed W is sucked and held on the first holding unit 510 and the non-bonded surface S_{N} of the supporting wafer S is sucked and held on second holding unit 511.

Then, the superimposed wafer T is heated to a predetermined, for example, 200° C. by the heating mechanisms 524, 541. Then, the adhesive G within the superimposed wafer T is softened.

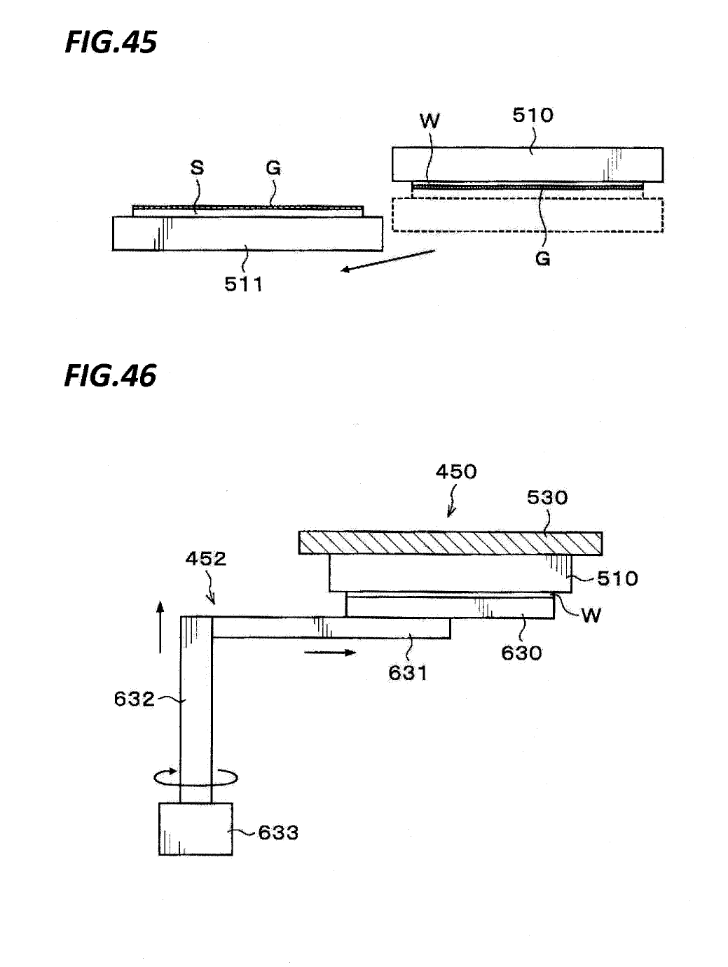

Subsequently, while the superimposed wafer T is heated by the heating mechanisms 524, 541 to maintain the softened state of the adhesive G, the second holding unit 511 and the supporting wafer S are moved in the vertical direction and the horizontal direction, that is, obliquely downward as illustrated in FIG. 44 by the moving mechanism 550. In addition, as illustrated in FIG. 45, the wafer to be processed W held by the first holding unit 510 and the supporting wafer S held by the second holding unit 511 are separated from each other (process B1 in FIG. 42).

At this time, the second holding unit 511 is moved by 100 μm in the vertical direction and also moved by 300 mm in the horizontal direction. Here, in the present exemplary embodiment, the thickness of the adhesive G within the superimposed wafer T is, for example, 30 μm to 40 μm, the height of electronic circuits (bumps) formed on the bonded surface W_{J} of the wafer to be processed W is, for example, 20 μm. Accordingly, the distance between the electronic circuits on the wafer to be processed W and the supporting wafer S is extremely small. Therefore, for example, when the second holding unit 511 is moved only in the horizontal direction, the electronic circuits and the supporting wafer S come in contact with each other and thus, the electronic circuits may be damaged. Thus, when the second holding unit 511 is moved in the horizontal direction as well as in the vertical direction as in the present exemplary embodiment, the contact between the electronic circuits and the supporting wafer S may be avoided such that the damage of the electronic circuits may be suppressed. Meanwhile, the ratio between the moving distance of the second holding unit 511 in the vertical direction and the moving distance of the second holding unit 511 in the horizontal direction may be set based on the height of the height of the electronic circuits (bumps) on the wafer to be processed W.

Then, the wafer to be processed W separated by the separating device 450 is conveyed to the first cleaning device 451 by the second conveyance device 452. Here, descriptions will be made on a method of conveying the wafer to be processed W by the second conveyance device 452.

As illustrated in FIG. 46, the support arm 631 is extended to place the Bernoulli chuck 630 below the wafer to be processed W held by the first holding unit 510. Then, the Bernoulli chuck 630 is moved up so that the suction of the wafer to be processed W from the suction tube 523 in the first holding unit 510 is stopped. Then, the wafer to be processed W is delivered from the first holding unit 510 to the Bernoulli chuck 630. At this time, the bonded surface W_{J} of the wafer to be processed W is held on the Bernoulli chuck 630 but in a non-contact state. As a result, the electronic circuits on the bonded surface W_{J} of the wafer to be processed W are not damaged.

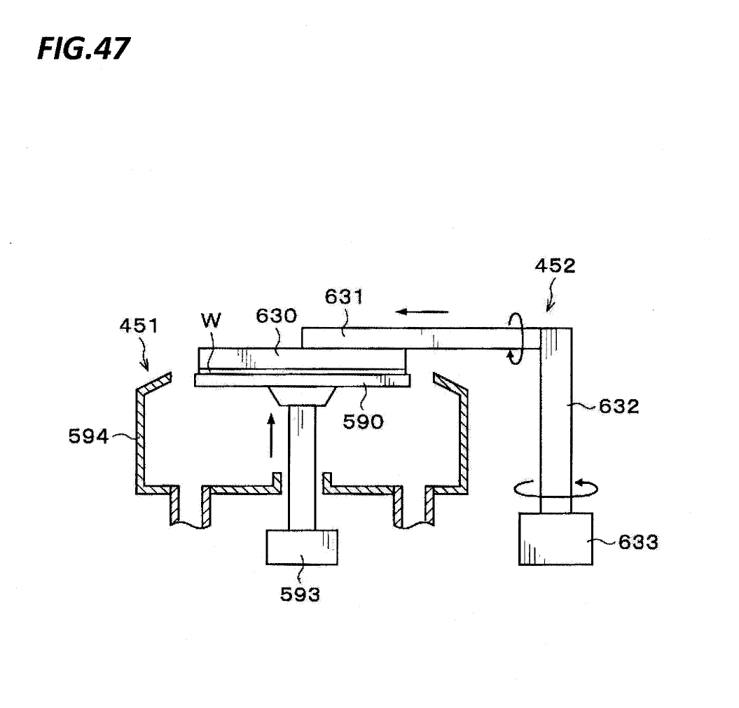

Subsequently, as illustrated in FIG. 47, the support arm 631 is rotated so as to move the Bernoulli chuck 630 to a position above the porous chuck 590 of the first cleaning device 451, and to invert Bernoulli chuck 630 so that the wafer to be processed W is directed downward. At this time, the porous chuck 590 is moved up to a position higher than the cup 594 and stood by at the position. Thereafter, the wafer to be processed W is delivered from the Bernoulli chuck 630 to the porous chuck 590 and sucked and held by the porous chuck 590.

When the wafer to be processed W is sucked and held by the porous chuck 590 as described above, the porous chuck 590 is moved down to a predetermined position. Subsequently, the cleaning liquid nozzle 603 of the standby section 605 is moved to a position above the central portion of the wafer to be processed W by the arm 601. Thereafter, a cleaning liquid is supplied to the bonded surface W_{J} of the wafer to be processed W from the cleaning liquid nozzle 603 while the wafer to be processed W is being rotated by the porous chuck 590. The supplied cleaning liquid is diffused over the entire bonded surface W_{J} of the wafer to be processed W by centrifugal force to clean the bonded surface W_{J} of the wafer to be processed W (process B2 in FIG. 42).

Here, the plurality of superimposed wafers T carried into the carry in/out station 421 have already been inspected as described above and the superimposed wafers T including a normal wafer to be processed W and the superimposed wafers T including a defective wafer to be processed W have been discriminated.

The normal wafer to be processed W separated from a normal superimposed wafer T is conveyed to the post-processing station 423 by the third conveyance device 461 after the bonded surface W_{I} is cleaned in process B2. Meanwhile, since the conveyance of the wafer to be processed W by the third conveyance device 461 is substantially the same as the conveyance of the wafer to be processed W by the second conveyance device 452 as described above, the description thereof will be omitted. Thereafter, a predetermined post-processing is performed on the wafer to be processed W in the post-processing station 423 (process B3 in FIG. 42). As a result, the wafer to be processed W is made into a product.

Meanwhile, a defective wafer to be processed W separated from a defective superimposed wafer T is conveyed to the carry in/out station 421 by the first conveyance device 440 after the bonded surface W_{J} is cleaned in process B2. Thereafter, the defective wafer to be processed W is carried out from the carry in/out station 421 to the outside and recovered (process B4 in FIG. 42).

While the above-described processes B2 to B4 are being performed on a wafer to be processed W, the supporting wafer S separated in the separating device 450 is conveyed to the second cleaning device 453 by the first conveyance device 440. Then, in the second cleaning device 453, the bonded surface S_{J} of the supporting wafer S is cleaned (process B5 of FIG. 42). Meanwhile, because the cleaning of the supporting wafer S in the second cleaning device 453 is the same as the cleaning of the wafer to be processed W in the first cleaning device 451 as described above, the description thereof will be omitted.

Thereafter, after the bonded surface S_{J} is cleaned, the supporting wafer S is conveyed to the carry in/out station 421 by the first conveyance device 440. Thereafter, the supporting wafer S is carried out from the carry in/out station 421 to the outside and recovered (process B6 of FIG. 42). As such, a series of separating processings of the wafer to be processed W and the supporting wafer S are finished.

According to an above-described exemplary embodiment, the substrate processing system 410 may perform the bonding processings and the separating processes of the wafer to be processed W and the supporting wafer S in unison because the substrate processing system is provided with the bonding system 1 and the separating system 420. Accordingly, the wafer processing throughput may be improved.

In addition, after the superimposed wafer T is separated into the wafer to be processed W and the supporting wafer S by the separating device 450 in the separating system 420, the separated wafer to be processed W may be cleaned in the first cleaning device 451 and the separated supporting wafer S may be cleaned in the second cleaning device 453. In this manner, according to the present exemplary embodiment, a series of separating processings from the separation of the wafer to be processed W and the supporting wafer S to the cleaning of the wafer to be processed W and the cleaning of the supporting wafer S may be efficiently performed within the single separating system 420. In addition, the cleaning of the wafer to be processed W and the cleaning of the supporting wafer S may be performed in parallel in the first cleaning device 451 and the second cleaning device 453. Further, while the wafer to be processed W and the supporting wafer S are being separated from each other in the separating device 450, another wafer to be processed W and another supporting wafer S may be processed in the first cleaning device 451 and second cleaning device 453, respectively. Accordingly, the separation of the wafer to be processed W and the supporting wafer S may be efficiently performed and thus, the separating processing throughput may be improved.

In addition, when the wafer to be processed W separated in the separating processing station 422 is a normal wafer to be processed W, a predetermined post-processing of the wafer to be processed W is performed in the post-processing station 5 and the wafer to be processed W is made into a product. Meanwhile, when the wafer to be processed W separated in the separating processing station 422 is a defective wafer to be processed W, the wafer to be processed W is recovered from the carry in/out station 421. Because only the normal wafer to be processed W is made into a product, a product yield may be improved. Further, the defective wafer to be processed W may be recovered and used again depending on the degree of defect. Therefore, resources may be effectively used and the manufacturing costs may be reduced.

As described above, processings from separation of a wafer to be processed W and a supporting wafer S to a post-processing of the wafer to be processed W may be performed in a series of processes, the wafer processing throughput may be further improved.

Further, because the supporting wafer S separated in the separating device 450 is recovered from the carry in/out station 421 after being cleaned, the supporting wafer S may be reused. Accordingly, resources may be effectively used and the manufacturing costs may be reduced.

In addition, because each of the second conveyance device 452 and the conveyance device 461 includes the Bernoulli chuck 630 configured to hold a wafer to be processed W, the wafer to be processed W may be properly held even if the wafer to be processed W has a very thin thickness. Further, in the second conveyance device 452, the bonded surface W_{J} of the wafer to be processed W is held on the Bernoulli chuck 630. Because the Bernoulli chuck 630 holds the wafer to be processed W in a non-contact state, electronic circuits on the bonded surface W_{J} of the wafer to be processed W are not damaged.

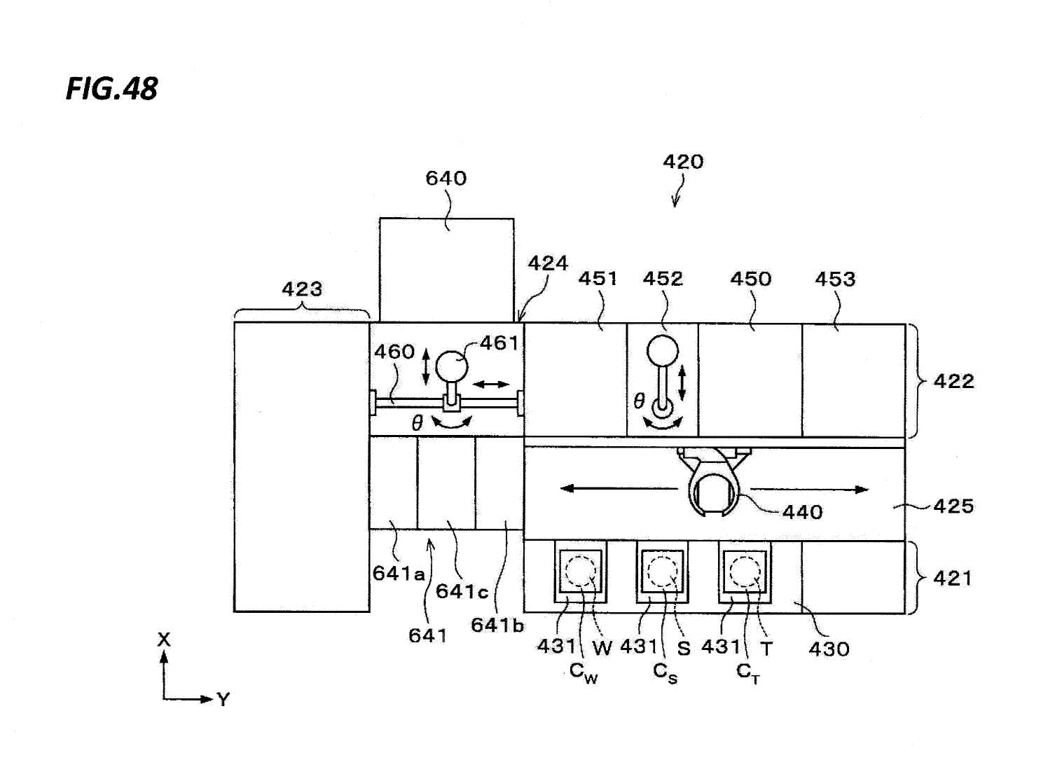

As illustrated in FIG. 48, the above-described separating system 420 may be further provided with an inspection device 640 as another inspection device to inspect a wafer to be processed W separated in the separating processing station 422. The inspection device 640 is arranged, for example, between the separating processing station 422 and the post-processing station 423. In such a case, the conveyance path 460 in the interface station 424 extends in the Y direction and the inspection device 640 is arranged in the interface station 424 at the positive side in the X direction.

The inspection device 640 performs an inspection of the surfaces of a wafer to be processed W (the bonded surface W_{J} and the non-bonded surface W_{N}). Specifically, for example, damage of the electronic circuits on the wafer to be processed W or residue of the adhesive G on the wafer to be processed W is inspected.

As illustrated in FIG. 48, a post-inspection cleaning device 641 may be additionally arranged in the interface station 424 at the negative side in the X direction to clean a wafer to be processed W which has been inspected. The post-inspection cleaning device 641 includes a bonded surface cleaning unit 641a configured to clean the bonded surface W_{J} of the wafer to be processed W, a non-bonded surface cleaning unit 641b configured to clean the non-bonded surface W_{N} of the wafer to be processed W, and an inverting section 641c configured to invert the top and bottom surfaces of the wafer to be processed W. Meanwhile, because the bonded surface cleaning unit 641a and the non-bonded surface cleaning unit 641b are substantially the same as the first cleaning device 451 in configuration, the descriptions thereof will be omitted.

In such a case, the inspection device 640 inspects whether residue of the adhesive G exists on the bonded surface W_{I} of the wafer to be processed W. When the residue of the adhesive G is confirmed in the inspection device 640, the wafer to be processed W is conveyed to the bonded surface cleaning unit 641a of the post-inspection cleaning device 641 by the third conveyance device 461 so that the bonded surface W_{J} is cleaned in the bonded surface cleaning unit 641a. When the bonded surface W_{J} is cleaned, the wafer to be processed W is conveyed to the inverting section 641c by the third conveyance device 461 and the top and bottom of the wafer to be processed W is inverted in the inverting section 641c. When no residue of the adhesive G is confirmed, the wafer to be processed W is inverted in the inverting section 641c without being conveyed to the bonded surface cleaning unit 641a.

Then, the inverted wafer to be processed W is conveyed to the inspection device 640 by the third conveyance device 461 and the non-bonded surface W_{N} is subjected to an inspection. In addition, when residue of the adhesive G is confirmed on the non-bonded surface W_{N}, the wafer to be processed W is conveyed to the non-bonded surface cleaning unit 641c by the third conveyance device 461 so that the non-bonded surface W_{N} is cleaned. Subsequently, the cleaned wafer to be processed W is conveyed to the post-processing station 423 by the third conveyance device 461. Meanwhile, when no residue of the adhesive G is confirmed in the inspection device 640, the wafer to be processed W is conveyed to the post-processing station 423 as it is without being conveyed to the non-bonded surface cleaning unit 641b.

According to an above-described exemplary embodiment, a wafer to be processed W is inspected by the inspection device 640. Thus, processing conditions in the separating system 420 may be corrected based on the inspection results. Accordingly, a wafer to be processed W and a supporting wafer S may be separated more properly. In addition, because the wafer to be processed W is inspected by the inspection device 640, the wafer to be processed W may be properly cleaned so that a subsequent post-processing may be properly performed.

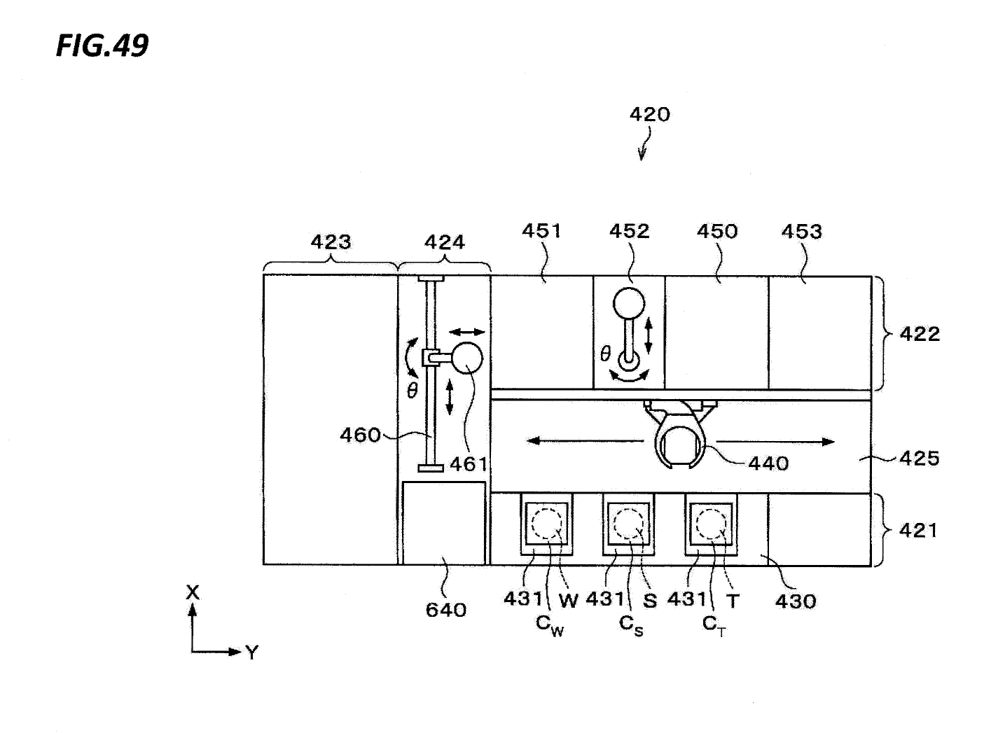

Meanwhile, the above-described inspection device 640 may be provided within the interface station 424 as illustrated in FIG. 49.

In an above-described exemplary embodiment, the second holding unit 511 is moved in the vertical direction and then in the horizontal direction in the separating device 450. However, in the separating device 450, the first holding unit 510 may be moved in the vertical direction and then in the horizontal direction. Alternatively, both the first holding unit 510 and the second holding unit 511 may be moved in the vertical direction and then in the horizontal direction.

In the separating device 450 as described above, the second holding unit 511 is moved in the vertical direction and then in horizontal direction. However, the second holding unit 511 may be moved only in the horizontal direction so that the moving speed of the second holding unit 511 may be changed. Specifically, the moving speed may be set to be low when starting to move the second holding unit 511 and then gradually accelerated. That is, when starting to move the second holding unit 511, the electronic circuits on the wafer to be processed W are apt to be affected by the adhesive G since the bonded area between the wafer to be processed W and the supporting wafer S is large. Thus, the moving speed of the second holding unit 511 is set to be low. Then, as the bonding area between the wafer to be processed W and the supporting wafer S is reduced, the electronic circuits on the wafer to be processed W are hardly affected by the adhesive G and thus, the moving speed of the second holding unit 511 is gradually accelerated. Even in such a case, the contact between the electronic circuits and the supporting wafer S may be avoided so as to suppress the damage of the electronic circuits.

In addition, in an above-described exemplary embodiment, the second holding unit 511 is moved in the vertical direction and then in the horizontal direction in the separating device 450. However, for example, when the distance between the electronic circuits on the wafer to be processed W and the supporting wafer S is sufficiently large, the second holding unit 511 may be moved only in the horizontal direction. In such a case, the contact between the electronic circuits and the supporting wafer S may be avoided, and the control of the movement of the second holding unit 511 is facilitated. Further, the second holding unit 511 may be moved only in the vertical direction so as to separate the wafer to be processed W and the supporting wafer S from each other, and an outer peripheral end of the second holding unit 511 may be moved only in the vertical direction to separate the wafer to be processed W and the supporting wafer S from each other.

In an above-described exemplary embodiment, a wafer to be processed W and a supporting wafer S are separated from each other in a state the wafer to be processed W is arranged at the top side and the supporting wafer S is arranged at the bottom side. However, the top and bottom arrangement of the wafer to be processed W and the supporting wafer S may be inverted.

In the second conveyance device 452 as described above, a plurality of supply ports may (not illustrated) be on a surface of the Bernoulli chuck 630 to supply a cleaning liquid. In such a case, when a wafer to be processed W is delivered from the Bernoulli chuck 630 to the porous chuck 590 of the first cleaning device 451, the cleaning liquid is supplied from the Bernoulli chuck 630 to the bonded surface W_{J} of the wafer to be processed W so that the Bernoulli chuck 630 itself as well as the bonded surface W_{J} may be cleaned. Then, a time for cleaning the wafer to be processed W in the first cleaning device 451 thereafter may be shortened and thus, the separating processing throughput may be improved. Further, because the Bernoulli chuck 630 may also be cleaned, the next wafer to be processed W may be properly conveyed.

In an above-described exemplary embodiment, the third conveyance device 461 is provided with the Bernoulli chuck 630. However, the third conveyance device 461 may be provided with a porous chuck (not illustrated) instead of the Bernoulli chuck 630. Even in such a case, a very thin wafer to be processed W may be properly sucked and held by the porous chuck.

In an above-described exemplary embodiment, a two-fluid nozzle is used for the cleaning liquid nozzle 603 of each of the first cleaning device 451 and the second cleaning device 453. However, the type of the cleaning liquid nozzle 603 is not limited thereto and may employ various nozzles. As for the cleaning liquid nozzle 603, for example, a nozzle body in which a cleaning liquid supply nozzle and an inert gas supply nozzle are integrated, a spray nozzle, a jet nozzle, or a megasonic nozzle may be used. Further, in order to improve the cleaning processing throughput, a cleaning liquid heated to, for example, 80° C., may be supplied.

In addition, in the first cleaning device 451 and second cleaning device 453, an isopropyl alcohol (“IPA”) supply nozzle may be provided in addition to the cleaning liquid nozzle 603. In such a case, the wafer to be processed W or the supporting wafer S is cleaned by the cleaning liquid from the cleaning liquid nozzle 603 and then the cleaning liquid on the wafer to be processed W or the supporting wafer S is substituted with the IPA. Then, the bonded surfaces W_{J}, S_{J} of the wafer to be processed W and the supporting wafer S may be more securely cleaned.

In the separating system 420 of an above-described exemplary embodiment, a temperature control device (not illustrated) may be provided so as to cool the wafer to be processed W heated in the separating device 450 to a predetermined temperature. In such a case, because the temperature of the wafer to be processed W may be controlled to a proper temperature, a subsequent processing may be performed more smoothly.

Further, in an above-described exemplary embodiment, a case in which a wafer to be processed W is subjected to a post-processing in the post-processing station 423 to be made into a product has been described. However, the present disclosure may also be applied to a case where a wafer to be used in, for example, a three-dimensional integration technology is separated from a supporting wafer. The three-dimensional integration technology refers to a technology that meets the recent high integration demands for semiconductor devices that stacks a plurality of highly integrated semiconductor devices three-dimensionally instead of arranging the plurality of semiconductor devices in a horizontal plane. In the three-dimensional integration technology, reduction of the thickness of wafers to be stacked is demanded and thus predetermined processings are performed on the wafers in a state where each of the wafers to be processed is bonded to a supporting wafer.

Various exemplary embodiments of the present disclosure have been described above with reference to the accompanying drawings. However, the present disclosure is not limited to the exemplary embodiments. It is apparent that a person skilled in the part may conceive various changes or modifications within an idea and scope defined by the claims and it will be understood that the changes and modifications naturally belong to the technical scope of the present disclosure. The present disclosure may be employed in various aspects without being limited to the exemplary embodiments. The present disclosure may also be applied to a case in which the substrate to be processed is a substrate other than a wafer such as, for example, a flat panel display (FPD) or a mask reticle for a photo mask. Further, the present disclosure may also be applied to a case in which the supporting substrate is a substrate other than a wafer such as, for example, a glass substrate.

### DESCRIPTION OF SYMBOL

1: bonding system
2: carry in/out station
3: bonding processing station
30 to 33: bonding device
40: coating device
41 to 46: heat treatment device
60: wafer conveyance region
110: delivery section
111: inverting section
112: conveyance section
113: bonding section
150: holding arm
151: holding member
152: cutout
153: first drive unit
154: second drive unit
160: position adjusting mechanism
170: first conveyance arm
171: second conveyance arm
182: O-ring
183: first guide member
184: second guide member
192: second holding member
193: placement portion
194: tapered portion
301: gas supply port
305: intake port
360: control unit
370: inspection device
410: substrate processing system
420: separating system
421: carry in/out station
422: separating processing station
423: post-processing station
424: interface station
425: wafer conveyance region
440: first conveyance device
450: separating device
451: first cleaning device
452: second conveyance device
453: second cleaning device
461: third conveyance device
630: Bernoulli chuck
640: inspection device
G: adhesive
S: supporting wafer
T: superimposed wafer
W: wafer to be processed

1. A bonding system that bonds a substrate to be processed and a supporting substrate with each other, the bonding system comprising:
a bonding processing station configured to perform a predetermined processing on a substrate to be processed and a supporting substrate; and
a carry in/out station configured to carry a substrate to be processed, a supporting substrate, or a superimposed substrate obtained by bonding a substrate to be processed and a supporting substrate with each other into/out of the bonding processing station,
wherein the bonding processing station includes:
a coating device configured to coat an adhesive to the substrate to be processed or the supporting substrate;
a heat treatment device configured to heat the substrate to be processed or the supporting substrate which is coated with the adhesive to a predetermined temperature;
a bonding device configured to invert front and back surfaces of the supporting substrate that is bonded to the substrate to be processed that is coated with the adhesive and heated to the predetermined temperature or the substrate to be processed that is bonded to the supporting substrate that is coated with the adhesive and heated to the predetermined temperature, and press the substrate to be processed and the supporting substrate with the adhesive being interposed therebetween, thereby bonding the substrate to be processed and the supporting substrate with each other; and
a conveyance region configured to convey the substrate to be processed, the supporting substrate or the superimposed substrate to the coating device, the heat treatment device, and the bonding device,
wherein the bonding device includes:
a delivery section configured to deliver the substrate to be processed, the supporting substrate or the superimposed substrate to or from the outside of the bonding device;
an inverting section configured to invert front and back surfaces of the supporting substrate that is bonded to the substrate to be processed that is coated with the adhesive and heated to the predetermined temperature or the substrate to be processed that is bonded to the supporting substrate that is coated with the adhesive and heated to the predetermined temperature;
a bonding section configured to press the substrate to be processed and the supporting substrate with the adhesive being interposed therebetween, thereby bonding the substrate to be processed and the supporting substrate with each other; and
a conveyance section configured to convey the substrate to be processed, the supporting substrate, or the superimposed substrate to the delivery section, the inverting section, and the bonding section, and
wherein the conveyance section includes:
a first conveyance arm that is provided with a first holding member configured to hold the back surface of the substrate to be processed, the supporting substrate, or the superimposed substrate; and
a second conveyance arm that is provided with a second holding member configured to hold an outer peripheral portion of the front surface of the substrate to be processed or the supporting substrate.

2. The bonding system of claim 1, further comprising an inspection device configured to inspect the superimposed substrate bonded by the bonding device.

3. The bonding system of claim 1, wherein an inside of the heat treatment device is capable of being maintained with an inert gas atmosphere.

4. The bonding system of claim 3, wherein a pressure within the heat treatment device is a negative pressure in relation to a pressure within the conveyance region.

5. The bonding system of claim 1, wherein the bonding device includes:
a delivery section configured to deliver the substrate to be processed, the supporting substrate or the superimposed substrate to or from the outside of the bonding device;
an inverting section configured to invert front and back surfaces of the supporting substrate that is bonded to the substrate to be processed that is coated with the adhesive and heated to the predetermined temperature or the substrate to be processed that is bonded to the supporting substrate that is coated with the adhesive and heated to the predetermined temperature;
a bonding section configured to press the substrate to be processed and the supporting substrate with the adhesive being interposed therebetween, thereby bonding the substrate to be processed and the supporting substrate with each other; and
a conveyance section configured to convey the substrate to be processed, the supporting substrate, or the superimposed substrate to the delivery section, the inverting section, and the bonding section.

6. The bonding system of claim 1,
wherein the second holding member includes a placement portion where the outer peripheral portion of the front surface of the substrate to be processed or the supporting substrate is placed, and a taper portion extending upward from the placing portion and having an inner surface expanded in a tapered shape from a bottom side to a top side.

7. The bonding system of claim 1, wherein the first conveyance arm includes a guide member provided outside the substrate to be processed, the supporting substrate, or the superimposed substrate which is held on the first holding member.

8. The bonding system of claim 1, wherein the first holding member holds the substrate to be processed, the supporting substrate, or the superimposed substrate by frictional force.

9. The bonding system of claim 1, wherein the inverting section includes an additional holding member configured to hold the supporting substrate or the substrate to be processed, and
a lateral surface of the additional holding member is formed with a cutout to hold the outer peripheral portion of the supporting substrate or the substrate to be processed.

10. The bonding system of claim 9, wherein a cutout is formed on a lateral surface of the additional holding member to hold the outer peripheral portion of the supporting substrate or the substrate to be processed.

11. The bonding system of claim 5, wherein a plurality of delivery sections are arranged in the vertical direction.

12. A substrate processing system comprising:
a bonding system as claimed in claim 1 that bonds a substrate to be processed and a supporting substrate with each other,
wherein the substrate processing system further comprises:
a separating system configured to separate the superimposed substrate bonded in the bonding system into the substrate to be processed and the supporting substrate,
wherein the separating system includes:
a separating processing station configured to perform a predetermined processing on the substrate to be processed, the supporting substrate, and the superimposed substrate;
a carry in/out station configured to carry the substrate to be processed, the supporting substrate, or the superimposed substrate into/out of the separating processing station; and
a conveyance device configured to convey the substrate to be processed, the supporting substrate or the superimposed substrate between the separating processing station and the carry in/out station, and
wherein the separating processing station includes:
a separating device configured to separate the superimposed substrate into the substrate to be processed and the supporting substrate;
a first cleaning device configured to clean the substrate to be processed which is separated in the separating device; and
a second cleaning device configured to clean the supporting substrate separated in the separating device.

13. The substrate processing system of claim 12, wherein the separating system includes:
an interface station configured to convey the substrate to be processed between the separating processing station and a post-processing station, the post-processing station being configured to perform a predetermined post-processing on the substrate to be processed which is separated in the separating processing station; and
a control unit configured to control the interface station and the conveyance device in such a manner that a superimposed substrate including a normal substrate to be processed and a superimposed substrate including a defective substrate to be processed are carried into the carry in/out station of the separating system, the normal substrate to be processed is cleaned in the second cleaning device and then conveyed to the post-processing station, and the defective substrate to be processed is cleaned in the first cleaning device and then returned to the carry in/out station.

14. The substrate processing system of claim 13, further comprising:
a control unit configured to control the interface station and the conveyance device in such a manner that a superimposed substrate including a normal substrate to be processed and a superimposed substrate including a defective substrate to be processed are carried into the carry in/out station of the separating system, the normal substrate to be processed is cleaned in the second cleaning device and then conveyed to the post-processing station, and the defective substrate to be processed is cleaned in the first cleaning device and then returned to the carry in/out station.

15. The substrate processing system of claim 13, further comprising an additional inspection device provided between the separating processing station and the post-processing station to inspect the substrate to be processed.

16. The substrate processing system of claim 13, wherein the interface station includes an additional conveyance device that is provided with a Bernoulli chuck or a porous chuck configured to hold the substrate to be processed.

17. The substrate processing system of claim 12, wherein the separating processing station includes an additional conveyance device configured to hold the substrate to be processed using a Bernoulli chuck and convey the substrate to be processed between the separating device and the first cleaning device.

18-20. (canceled)
